(19) United States
(12) Patent Application Publication
(10) Pub. No.: US 2026/0096451 A1
(43) Pub. Date: Apr. 2, 2026

(54) ELECTRONIC DEVICE

(71) Applicant: Rohm Co., Ltd., Kyoto-shi (JP)

(72) Inventors: Hiroaki SAWAOKA, Kyoto-shi (JP); Daiki YANAGISHIMA, Kyoto-shi (JP)

(21) Appl. No.: 19/341,454

(22) Filed: Sep. 26, 2025

(30) Foreign Application Priority Data
Oct. 1, 2024 (JP) 2024-172420

(51) Int. Cl. H01L 23/495; H01L 23/31; H01L 23/00; H01L 25/18

(52) U.S. Cl. CPC H10W 70/465; H10W 70/411; H10W 74/111; H10W 90/811; H10W 90/00; H10W 90/753

(57) ABSTRACT

The electronic device includes a first electronic component, a second electronic component, a sealing resin covering the first/second electronic components, first, second, third and fourth leads, a first die pad supporting the first electronic component, and a second die pad supporting the second electronic component. The sealing resin has resin side surfaces facing in orthogonal directions perpendicular to a thickness direction of the sealing resin. A first outer portion of the first lead, a second outer portion of the second lead and a third outer portion of the third lead are exposed from one or more resin side surfaces different from the resin side surface from which a fourth outer portion of the fourth lead is exposed.

### CROSS REFERENCE TO RELATED APPLICATIONS

The present invention claims priority under 35 U.S.C. §119 to Japanese Application No. 2024-172420, filed on October 1, 2024, the entire contents of which being incorporated herein by reference.

### TECHNICAL FIELD

The present disclosure relates to electronic devices.

### BACKGROUND ART

Electric vehicles have been becoming more common in recent years. JP-A-2012-95427 discloses circuits for monitoring the voltage of the battery installed in an electric vehicle and thus for controlling the inverter. With the circuits, it is possible to prevent overvoltage from being supplied to the inverter in driving the motor.

The motor control device disclosed in JP-A-2012-95427 includes a voltage detection circuit (high-voltage battery voltage detection circuit) for monitoring the battery voltage. The voltage detection circuit is packaged as a single electronic device and can be mounted on a circuit board of the electric vehicle. In packaging, a Small Outline Package (SOP) may be adopted. In this case, the lead terminals protruding from the sealing resin are arranged at equal intervals.

### BRIEF DESCRIPTION OF DRAWINGS

FIG. 1 is a plan view showing an electronic device according to a first embodiment.

FIG. 2 corresponds to the plan view of FIG. 1, with the sealing resin shown by imaginary lines.

FIG. 3 is a front view of the electronic device of the first embodiment.

FIG. 4 is a rear view of the electronic device of the first embodiment.

FIG. 5 is a left side view of the electronic device of the first embodiment.

FIG. 6 is a right side view of the electronic device of the first embodiment.

FIG. 7 is a cross-sectional view along line VII-VII in FIG. 2.

FIG. 8 is a cross-sectional view along line VIII-VIII in FIG. 2.

FIG. 9 is a cross-sectional view along line IX-IX in FIG. 2.

FIG. 10 shows the circuit configuration of the electronic device of the first embodiment.

FIG. 11 is a plan view showing an electronic device according to a variation of the first embodiment, with the sealing resin shown by imaginary lines.

FIG. 12 is a plan view showing an electronic device according to a second embodiment, with the sealing resin shown by imaginary lines.

FIG. 13 is a plan view showing an electronic device according to a third embodiment, with the sealing resin shown by imaginary lines.

FIG. 14 is a plan view showing an electronic device according to a first variation of the third embodiment, with the sealing resin shown by imaginary lines.

FIG. 15 is a plan view showing an electronic device according to a second variation of the third embodiment, with the sealing resin shown by imaginary lines.

FIG. 16 is a plan view showing an electronic device according to a fourth embodiment, with the sealing resin shown by imaginary lines.

FIG. 17 is a plan view showing an electronic device according to a variation of the fourth embodiment, with the sealing resin shown by imaginary lines.

FIG. 18 is a plan view showing another configuration of the electronic device shown in FIG. 17, with the sealing resin shown by imaginary lines.

FIG. 19 is a plan view showing another example (Example 1) of the electronic device of the present disclosure, with the sealing resin shown by imaginary lines.

FIG. 20 shows the circuit configuration of the electronic device shown in FIG. 19.

FIG. 21 is a plan view showing another example (Example 2) of the electronic device of the present disclosure, with the sealing resin shown by imaginary lines.

FIG. 22 shows the circuit configuration of the electronic device shown in FIG. 21.

FIG. 23 is a plan view showing another example (Example 3) of the electronic device of the present disclosure, with the sealing resin shown by imaginary lines.

FIG. 24 is a plan view showing another example (Example 4) of the electronic device of the present disclosure, with the sealing resin shown by imaginary lines.

FIG. 25 is a plan view showing another example (Example 5) of the electronic device of the present disclosure, with the sealing resin shown by imaginary lines.

FIG. 26 is a plan view showing another example (Example 6) of the electronic device of the present disclosure, with the sealing resin shown by imaginary lines.

FIG. 27 is a plan view showing another example (Example 7) of the electronic device of the present disclosure, with the sealing resin shown by imaginary lines.

FIG. 28 is a cross-sectional view along line XXVIII-XXVIII in FIG. 27.

### DETAILED DESCRIPTION OF EMBODIMENTS

The following describes preferred embodiments of electronic devices of the present disclosure with reference to the accompanying drawings. In the present disclosure, the same or similar elements/components/etc. are indicated by the same reference numerals and redundant explanations may be omitted. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specified, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specified, “the object A is disposed directly in or on the object B”, and “the object A is disposed in or on the object B, with something else interposed between the object A and the object B”. Further, the expression “An object A is located on an object B” implies the situation where, unless otherwise specified, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specified, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### FIRST EMBODIMENT:

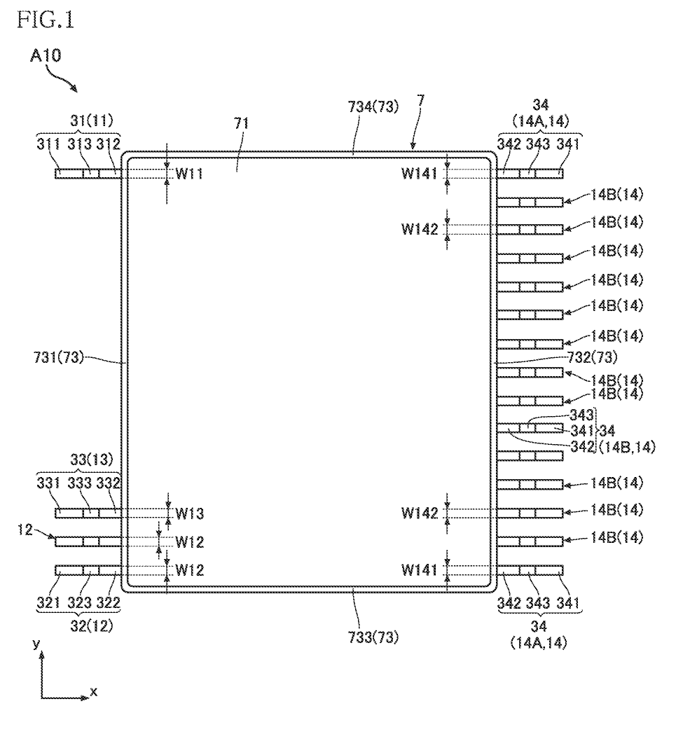

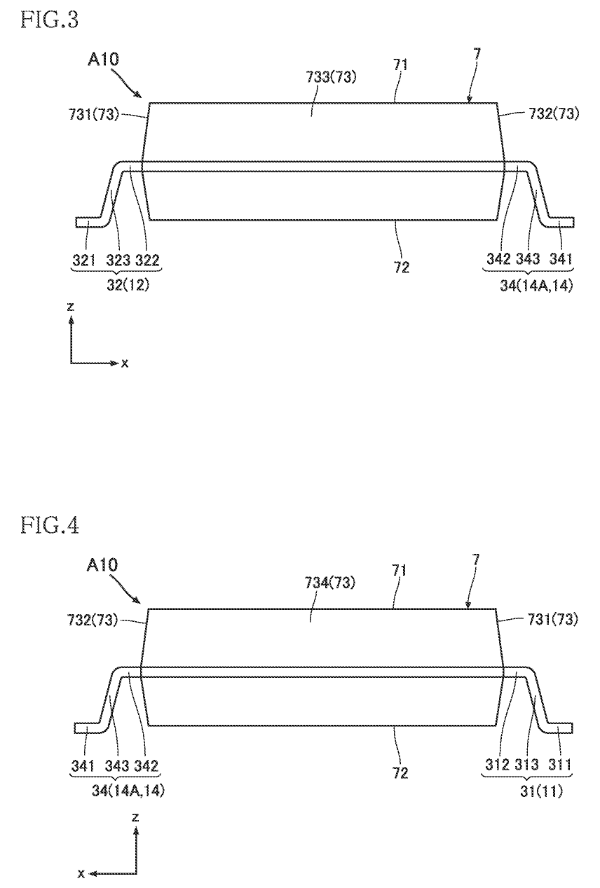

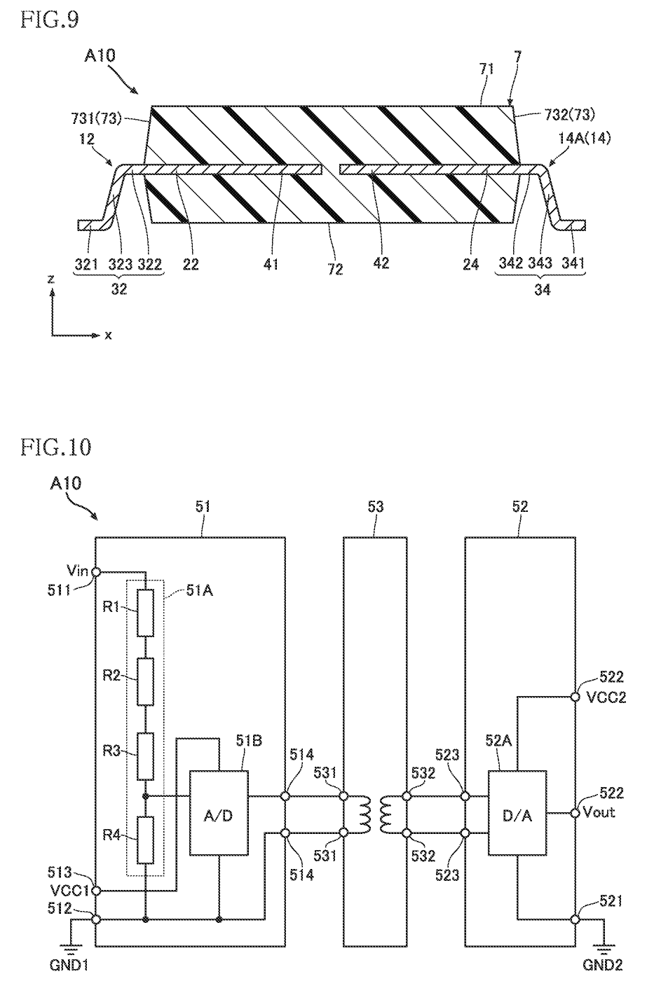

FIGS. 1 to FIG. 10 show an electronic device A10 according to a first embodiment. The electronic device A10 comprises a first lead 11, two second leads 12, a third lead 13, a plurality of fourth leads 14, a first die pad 41, a second die pad 42, a first electronic component 51, a second electronic component 52, a third electronic component 53, a plurality of connecting members 61 to 67, and a sealing resin 7. The applications of the electronic device A10 are not particularly limited. For example, it may be used to detect the battery voltage of an electric vehicle. The electronic device A10 may detect voltages other than the electric vehicle battery voltage, or it may detect voltages used in industrial equipment, home appliances, or power supplies instead of electric vehicles. The electronic device A10 is a surface-mount type packaged semiconductor device. In the present embodiment, as understood from FIGS. 1 to 9, the device A10 is a Small Outline Package (SOP) type.

For convenience of explanation, reference is made to mutually orthogonal thickness direction z, first direction x and second direction y. The thickness direction z may correspond to the thickness direction of the electronic device A10. The first direction x is orthogonal to the thickness direction z. The second direction y is orthogonal to the thickness direction z and the first direction x. In the description below, one side in the thickness direction z may be referred to as the upper side, and the other side in the thickness direction z may be referred to as the lower side. Descriptions such as “upper,” “lower,” “upper side,” “lower side,” “upper surface,” “lower surface” and the like only indicate the relative positional relationship of the related components with respect to the thickness direction z and do not necessarily define the relationship with respect to the direction of gravity.

The first lead 11, the two second leads 12, the third lead 13, the fourth leads 14, the first die pad 41, and the second die pad 42 each contain metals such as Cu (copper), Ni (nickel), and Fe (iron), but the constituent materials are not limited to these examples. The first lead 11, two second leads 12, third lead 13, fourth leads 14, first die pad 41, and second die pad 42 are obtained from the same lead frame. The first lead 11, two second leads 12, third lead 13, fourth leads 14, first die pad 41, and second die pad 42 may be formed by a method selected from: punching, bending, etching and the like conducted on a metal sheet material. The first lead 11, the two second leads 12, the third lead 13, the fourth leads 14, the first die pad 41, and the second die pad 42 may, as appropriate, be provided with a plating layer(s) made of Ag (silver), Ni, Au (gold) and the like.

The first lead 11, the two second leads 12, the third lead 13, and the fourth leads 14 are each electrically connected to the first electronic component 51, or the second electronic component 52, or the third electronic component 53, thereby constituting a conduction path(s) in the electronic device A10. The fourth leads 14 may include one or more leads that are not electrically connected to none of the first electronic component 51, the second electronic component 52, and the third electronic component 53. The first lead 11, two second leads 12, third lead 13, and fourth leads 14 are spaced apart from each other. The first lead 11, the two second leads 12, the third lead 13, and the fourth leads 14 each have a part covered by the sealing resin 7 and another part exposed from the sealing resin 7.

The first lead 11 includes a first inner portion 21 and a first outer portion 31. The first inner portion 21 and the first outer portion 31 are connected to each other to form a single, integral piece. The boundary between the first inner portion 21 and the first outer portion 31, in plan view (i.e., as viewed in the thickness direction z), overlaps with the periphery or outer edge of the sealing resin 7.

The first inner portion 21 is the part of the first lead 11 covered by the sealing resin 7. The first inner portion 21 connects to the first outer portion 31 and extends inward from the first outer portion 31 within the sealing resin 7. The first inner portion 21 is spaced apart from the first die pad 41. In the illustrated example, the first inner portion 21 extends along the first direction x from the first outer portion 31 and then bends toward the first die pad 41. The plan-view shape of the first inner portion 21 is not limited to that of the illustrated example.

The first outer portion 31 is the part of the first lead 11 exposed from the sealing resin 7. In the present embodiment, the first outer portion 31 protrudes in the first direction x from the sealing resin 7 in plan view. The first outer portion 31 has a rectangular shape having longer sides extending in the first direction x in plan view. The first outer portion 31 is curved in a gull-wing shape as viewed in the second direction y. The width W11 (see FIG. 1) of the first outer portion 31 is not particularly limited, but is, for example, not less than 0.1 mm and not more than 1.5 mm. In the illustrated example, the width W11 corresponds to the dimension in the second direction y. The first outer portion 31 includes a first mounting portion 311, a first root portion 312, and a first intermediate portion 313.

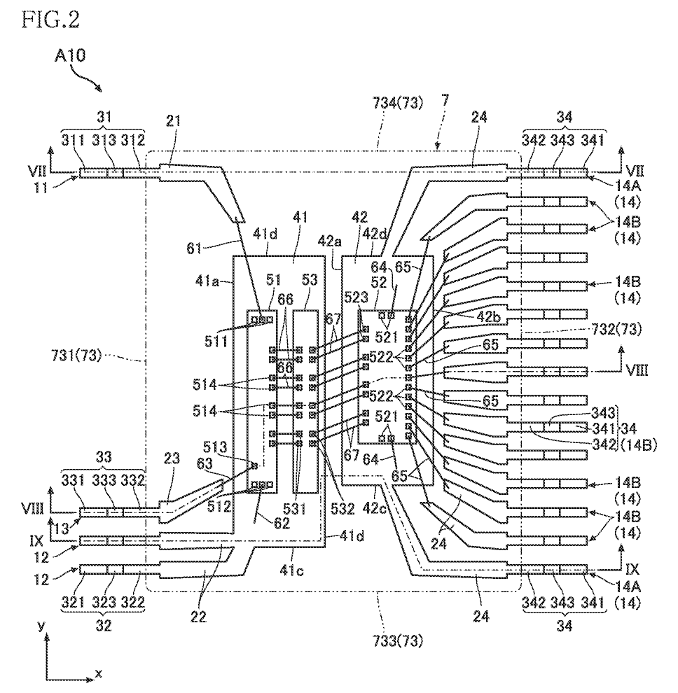

The first mounting portion 311 is a tip portion of the first outer portion 31. The first mounting portion 311 is the part that is bonded to a circuit board when mounting the electronic device A10 onto the circuit board. As shown in FIGS. 1 and 2, the first mounting portion 311 is located at the end opposite from the sealing resin 7 with respect to the first direction x. Therefore, the first mounting portion 311 is located farther from the sealing resin 7 than are the first root portion 312 and the first intermediate portion 313 in the first direction x. The first mounting portion 311 is located below the first root portion 312 in the thickness direction z.

The first root portion 312 is a proximal part of the first outer portion 31. As shown in FIGS. 1 and 2, the first root portion 312 is located at the end of the first outer portion 31 closer to the sealing resin 7 in the first direction x. Therefore, the first root portion 312 is positioned closer to the sealing resin 7 than are the first mounting portion 311 and the first intermediate portion 313 in the first direction x. The first root portion 312 is positioned above the first mounting portion 311 in the thickness direction z and protrudes from a central portion of the sealing resin 7 in the thickness direction z.

The first intermediate portion 313 connects the first mounting portion 311 and the first root portion 312 to each other. The first intermediate portion 313 is inclined relative to the first mounting portion 311 and the first root portion 312 as viewed in the second direction y. In the present embodiment, the first intermediate portion 313 is inclined relative to the thickness direction z.

Each of the two second leads 12 includes a second inner portion 22 and a second outer portion 32. In each second lead 12, the second inner portion 22 and the second outer portion 32 are connected to each other to form a single piece. In each second lead 12, the boundary between the second inner portion 22 and the second outer portion 32 overlaps with the periphery of the sealing resin 7 in plan view. Unless otherwise specified, the configurations of the second inner portion 22 and second outer portion 32 described below are common to the respective second leads 12.

The second inner portion 22 is the part of the second lead 12 covered by the sealing resin 7. The second inner portion 22 connects to the second outer portion 32 and extends inward from the second outer portion 32 into the sealing resin 7. In the present embodiment, the second inner portion 22 connects to the first die pad 41. In the illustrated example, the first die pad 41 has four corners, and the second inner portion 22 connects to one of them which is, in plan view, closest to the second outer portion 32.

The second outer portion 32 is the part of the second lead 12 exposed from the sealing resin 7. In the present embodiment, the second outer portion 32 protrudes from the sealing resin 7 in the first direction x in plan view. The second outer portion 32 has a rectangular shape having longer sides extending in the first direction x in plan view. The second outer portion 32 is curved in a gull-wing shape as viewed in the second direction y. The second outer portions 32 of the two second leads 12 are arranged in the second direction y. The width W12 (see FIG. 1) of the second outer portion 32 is not particularly limited, and not less than 0.1 mm and not more than 1.5 mm, for example. In the illustrated example, the width W12 corresponds to the dimension along the second direction y. The second outer portion 32 includes a second mounting portion 321, a second root portion 322, and a second intermediate portion 323.

The second mounting portion 321 is a tip portion of the second outer portion 32. The second mounting portion 321 is the part that is bonded to the circuit board when mounting the electronic device A10 onto the circuit board. As shown in FIG.s 1 and 2, the second mounting portion 321 is located at the end opposite from the sealing resin 7 in the first direction x. Therefore, the second mounting portion 321 is positioned farther from the sealing resin 7 than are the second root portion 322 and the second intermediate portion 323 in the first direction x. The second mounting portion 321 is positioned downward in the thickness direction z relative to the second root portion 322.

The second root portion 322 is the proximal part of the second outer portion 32. As shown in FIGS. 1 and 2, the second root portion 322 is located at one of the ends of the second outer portion 32 which is closer to the sealing resin 7 in the first direction x. Therefore, the second root portion 322 is positioned closer to the sealing resin 7 than are the second mounting portion 321 and the second intermediate portion 323 in the first direction x. The second root portion 322 is positioned above the second mounting portion 321 in the thickness direction z and protrudes from the central portion of the sealing resin 7 in the thickness direction z. In the illustrated example, the third root portion 332 of one of the two second leads 12 overlaps with the first die pad 41 as viewed in the first direction x, while the third root portion 332 of the other of the two second leads 12 does not overlap with the first die pad 41 as viewed in the first direction x. Differing from this example, both or none of the third root portions 332 of the two second leads 12 may overlap with the first die pad 41 as viewed in the first direction x.

The second intermediate portion 323 connects the second mounting portion 321 and the second root portion 322 to each other. The second intermediate portion 323 is inclined relative to the second mounting portion 321 and the second root portion 322 as viewed in the second direction y. In the present embodiment, the second intermediate portion 323 is inclined relative to the thickness direction z.

The third lead 13 includes a third inner portion 23 and a third outer portion 33. The third inner portion 23 and the third outer portion 33 are connected to each other to form a single piece. The boundary between the third inner portion 23 and the third outer portion 33 overlaps with the periphery of the sealing resin 7 in plan view. The third inner portion 23 is a part of the third lead 13 covered by the sealing resin 7. The third inner portion 23 connects to the third outer portion 33 and extends inward from the third outer portion 33 into the sealing resin 7. The third inner portion 23 is spaced apart from the first die pad 41.

The third outer portion 33 is the part of the third lead 13 exposed from the sealing resin 7. In the present embodiment, the third outer portion 33 protrudes from the sealing resin 7 in the first direction x in plan view. The third outer portion 33 has a rectangular shape having longer sides extending in the first direction x in plan view. The third outer portion 33 is curved in a gull-wing shape as viewed in the second direction y. The width W13 (see FIG. 1) of the third outer portion 33 is not limited, but is, for example, not less than 0.1 mm and not more than 1.5 mm. In the illustrated example, the width W13 corresponds to the dimension in the second direction y. The third outer portion 33 includes a third mounting portion 331, a third root portion 332, and a third intermediate portion 333.

The third mounting portion 331 is a tip portion of the third outer portion 33. The third mounting portion 331 is the part that is bonded to the circuit board when mounting the electronic device A10 onto the circuit board. As shown in FIG. 1 and FIG. 2, the third mounting portion 331 is located at the end opposite from the sealing resin 7 in the first direction x. Therefore, the third mounting portion 331 is positioned farther from the sealing resin 7 in the first direction x than are the third root portion 332 and the third intermediate portion 333. The third mounting portion 331 is positioned downward in the thickness direction z relative to the third root portion 332.

The third root portion 332 is the proximal part of the third outer portion 33. As shown in FIGS. 1 and 2, the third root portion 332 is located at one of the ends of the third outer portion 33 closer to the sealing resin 7 in the first direction x. Therefore, in the first direction x, the third root portion 332 is positioned closer to the sealing resin 7 than are the third mounting portion 331 and the third intermediate portion 333. The third root portion 332 is positioned above the third mounting portion 331 in the thickness direction z and protrudes from the central portion of the sealing resin 7 in the thickness direction z.

The third intermediate portion 333 connects the third mounting portion 331 and the third root portion 332 to each other. The third intermediate portion 333 is inclined relative to the third mounting portion 331 and the third root portion 332 as viewed in the second direction y. In the present embodiment, the third intermediate portion 333 is inclined relative to the thickness direction z.

The fourth leads 14, as shown in FIG. 1, comprise two support leads 14A and multiple signal leads 14B. The two support leads 14A connect to the second die pad 42. The plurality of signal leads 14B are each spaced apart from the second die pad 42. In the illustrated example, the fourth leads 14 include two support leads 14A and thirteen signal leads 14B, but the number of support leads 14A and the number of signal leads 14B are not limited to this example.

The fourth leads 14 (two support leads 14A and multiple signal leads 14B) each comprise a fourth inner portion 24 and a fourth outer portion 34. In each fourth lead 14, the fourth inner portion 24 and the fourth outer portion 34 are connected to each other to form a single piece. In each fourth lead 14, the boundary between the fourth inner portion 24 and the fourth outer portion 34, in plan view, coincides with the periphery of the sealing resin 7. Unless otherwise specified, the configurations of the fourth inner portion 24 and the fourth outer portion 34 described below are common to the respective fourth leads 14.

The fourth inner portion 24 is the part of the fourth lead 14 covered by the sealing resin 7. The fourth inner portion 24 connects to the fourth outer portion 34 and extends from the fourth outer portion 34 into the contents of the sealing resin 7. As shown in FIG. 2, the fourth inner portion 24 of each of the two support leads 14A connects to the second die pad 42, while the fourth inner portion 24 of each of the signal leads 14B is spaced apart from the second die pad 42.

The fourth outer portion 34 is the part of the fourth lead 14 exposed from the sealing resin 7. In the present embodiment, the fourth outer portion 34 protrudes in the first direction x from the sealing resin 7 in plan view. The fourth outer portion 34 has a rectangular shape having longer sides extending in the first direction x in plan view. The fourth outer portion 34 is curved in a gull-wing shape as viewed in the second direction y. The fourth outer portions 34 of the fourth leads 14 are arranged in the second direction y. In the present embodiment, the width W141 (see FIG. 1) of the fourth outer portion 34 of each support lead 14A and the width W142 (see FIG. 1) of the fourth outer portion 34 of each signal lead 14B are the same. These widths W141 and W142 (see FIG. 1) are not particularly limited, but are, for example, not less than 0.1 mm and not more than 1.5 mm. In the illustrated example, these widths W141 and W142 correspond to the dimensions in the second direction y. In the electronic device A10, the fourth outer portion 34 of one of the two support leads 14A overlaps with the first outer portion 31 of the first lead 11 as viewed in the first direction x, and the fourth outer portion 34 of the other of the two support leads 14A overlaps with the second outer portion 32 of the outer second lead 12 as viewed in the first direction x. Each of the fourth outer portions 34 comprises a fourth mounting portion 341, a fourth root portion 342, and a fourth intermediate portion 343.

The fourth mounting portion 341 is a tip portion of the fourth outer portion 34. The fourth mounting portion 341 is the part that is bonded to the circuit board when mounting the electronic device A10 onto the circuit board. As shown in FIGS. 1 and 2, the fourth mounting portion 341 is located at the end opposite from the sealing resin 7 in the first direction x. Therefore, the fourth mounting portion 341 is located farther from the sealing resin 7 in the first direction x than are the fourth root portion 342 and the fourth intermediate portion 343. The fourth mounting portion 341 is located downward in the thickness direction z relative to the fourth root portion 342.

The fourth root portion 342 is the proximal part of the fourth outer portion 34. As shown in FIGS. 1 and 2, the fourth root portion 342 is located at one of the ends of the fourth outer portion 34 closer to the sealing resin 7 in the first direction x. Therefore, in the first direction x, the fourth root portion 342 is positioned closer to the sealing resin 7 than are the fourth mounting portion 341 and the fourth intermediate portion 343. The fourth root portion 342 is positioned above the fourth mounting portion 341 in the thickness direction z and protrudes from the central portion of the sealing resin 7 in the thickness direction z.

The fourth intermediate portion 343 connects the fourth mounting portion 341 and the fourth root portion 342 to each other. The fourth intermediate portion 343 is inclined relative to the fourth mounting portion 341 and the fourth root portion 342 as viewed in the second direction y. In the present embodiment, the fourth intermediate portion 343 is inclined relative to the thickness direction z.

Among the fourth leads 14, the fourth outer portions 34 of the plurality of signal leads 14B are arranged in the second direction y. The fourth outer portions 34 of the two support leads 14A are arranged outside of the fourth outer portions 34 of the signal leads 14B in the second direction y. The fourth outer portions 34 of the respective fourth leads 14 (two support leads 14A and signal leads 14B) are parallel to each other in plan view.

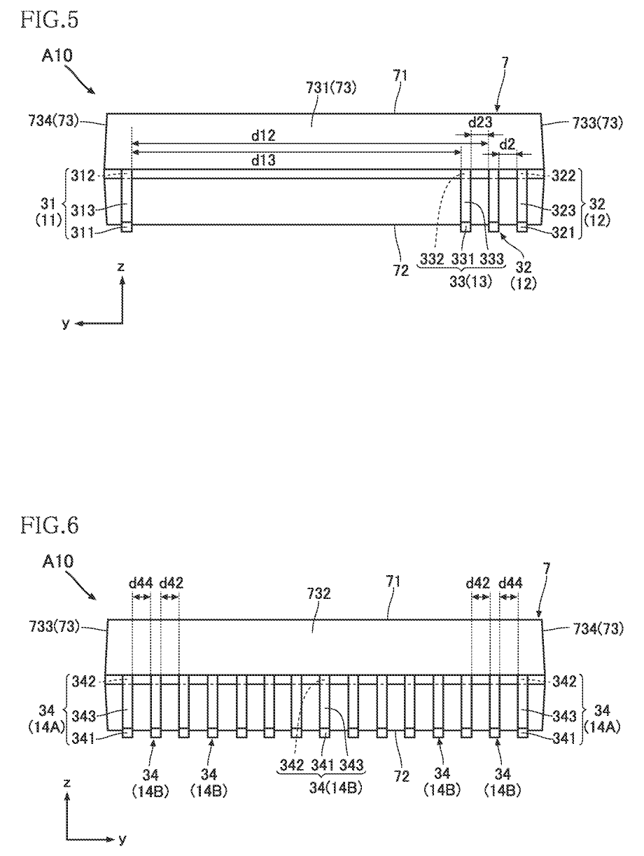

In the electronic device A10, the first outer portion 31 and the third outer portion 33 are spaced apart by a distance or spacing d13 (see FIG. 5) in the first direction x. The third outer portion 33 is space apart from one of the two second outer portions 32 (the second outer portion 32 closer to the third outer portion 33) by a distance d23 (see FIG. 5). The two second outer portions 32 are spaced apart from each other by a distance d2 (see FIG. 5) in the first direction x. The first outer portion 31 and the inner second outer portion 32 are spaced apart by a distance d12 (see FIG. 5) in the first direction x. In the electronic device A10, the fourth outer portion 34 of each support lead 14A and the fourth outer portion 34 of the closest signal lead 14B are spaced apart by a distance d44 (see FIG. 6) in the first direction x. The fourth outer portions 34 of two adjacent signal leads 14B are spaced apart by a distance d42 (see FIG. 6) in the first direction x. In the present embodiment, the distances d2, d23, d42, and d44 are equal to each other. The values of these distances d2, d23, d42, and d44 are not particularly limited, but are, for example, not less than 5 mm and not more than 10 mm. The distance d13 is greater than the distances d2, d23, d42 and d44. For example, the distance d13 is not less than 10 times the distance d42 and not more than 20 times the distance d42. The value of the distance d13 is not particularly limited, but is, for example, not less than 0.25 mm and not more than 5 mm. When the potential difference between the first outer portion 31 and the second outer portion(s) 32 is approximately 800 V, the distance d12 may preferably be 4 mm or more for suppressing the occurrence of short-circuit between the first outer portion 31 and the second outer portion 32.

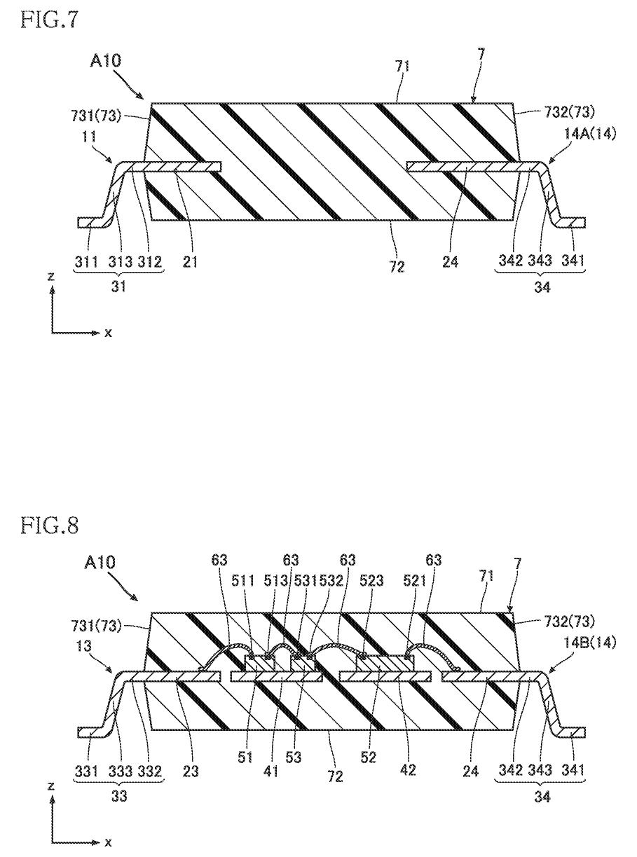

The first die pad 41 and the second die pad 42 are spaced apart from each other. The planar shapes of the first die pad 41 and the second die pad 42 are not particularly limited, but in the illustrated example, they are rectangular. The first die pad 41 and the second die pad 42 are arranged side by side, for example, in the first direction x, as shown in FIGS. 2 and 7. The first die pad 41 is closer, in the first direction x, to the first lead 11, the two second lateral leads 12 and the third lead 13 than is the second die pad 42.

The first electronic component 51 is bonded to the first die pad 41. The first die pad 41 supports the first electronic component 51. The first die pad 41 connects to the two second leads 12. The first die pad 41 and the two second leads 12 are formed integral, as a single piece. In the illustrated example where the first die pad 41 is rectangular in plan, as shown in FIG. 2, the first die pad 41 has two edges or sides 41a, 41b spaced apart in the first direction x and two edges or sides 41c, 41d spaced apart in the second direction y. The two edges 41a and 41b extend along the second direction y and are, for example, substantially parallel to each other. The two edges 41c and 41d extend along the first direction x and are, for example, substantially parallel to each other. In the illustrated example, the first die pad 41 has four corners, and the two second leads 12 are connected to one of the corners (formed by the two edges 41a and 41c) that is close to the second outer portions 32.

The second electronic component 52 is bonded to the second die pad 42. The second die pad 42 supports the second electronic component 52. The second die pad 42 is connected to the two support leads 14A. The second die pad 42 and the two support leads 14A are formed integral as a single piece. In the illustrated example where the second die pad 42 is rectangular, as shown in FIG. 2, the second die pad 42 has two edges 42a, 42b spaced apart in the first direction x and two edges 42c, 42d spaced apart in the second direction y. The two edges 42a and 42b extend along the second direction y and are, for example, substantially parallel to each other. The two edges 42c and 42d extend along the first direction x and are, for example, substantially parallel to each other. In the illustrated example, the two support leads 14A are connected to the centers of the edges 42a and 42b, respectively, in the first direction x.

The first electronic component 51 and the second electronic component 52 are elements that perform desired electrical functions within the electronic device A10. The functions of the first electronic component 51 and the second electronic component 52 are not particularly limited, but the electronic device A10 of the present embodiment is configured to detect voltage by means of the first electronic component 51 and the second electronic component 52.

The first electronic component 51 is mounted on the first die pad 41. In the present embodiment, the first electronic component 51 outputs a signal (first signal) for detecting the potential difference between the first lead 11 and each second lead 12 and transmits the signal to the second electronic component 52 via the third electronic component 53.

As shown in FIG. 2, the first electronic component 51 has a plurality of electrode pads 511, 512, 513, 514. The electrode pads 511, 512, 513, 514 are arranged on the upper surface (the surface facing upward in the thickness direction z) of the first electronic component 51. The composition of each electrode pad 511, 512, 513, 514 is not particularly limited, but may include, for example, aluminum.

The second electronic component 52 is mounted on the second die pad 42. In the present embodiment, the second electronic component 52 receives the above-mentioned first signal via the third electronic component 53 and outputs a signal (second signal) corresponding to the potential difference between the first lead 11 and each second lead 12. As such, the second electronic component 52 outputs a detection signal of the voltage applied between the first lead 11 and each second lead 12 as a second signal.

As shown in FIG. 2, the second electronic component 52 has a plurality of electrode pads 521, 522, 523. The electrode pads 521, 522, 523 are arranged on the upper surface (the surface facing upward in the thickness direction z) of the second electronic component 52. The composition of each electrode pad 521, 522, 523 is not particularly limited, but includes, for example, aluminum.

The third electronic component 53 relays signals between the first electronic component 51 and the second electronic component 52. In the present embodiment, the third electronic component 53 is an insulating element that transmits electrical signals in an insulated state. The third electronic component 53 is, for example, an inductively coupled isolation element (e.g., a transformer chip), which transmits electrical signals in an insulated state by inductively coupling two coils (inductors). The third electronic component 53 may also be a capacitive isolation element (e.g., a capacitor) or a photocoupler, instead of an inductively coupled isolation element. In the illustrated example, the third electronic component 53 is mounted on the first die pad 41. In the present embodiment, the third electronic component 53 receives the first signal input from the first electronic component 51 and outputs the second signal to the second electronic component 52. In the illustrated example, the third electronic component 53 is disposed between the first electronic component 51 and the second electronic component 52 in the first direction x.

As shown in FIG. 2, the third electronic component 53 has a plurality of electrode pads 531, 532. The electrode pads 531, 532 are arranged on the upper surface (the surface facing upward in the thickness direction z) of the third electronic component 53. Each electrode pad 531 is electrically connected, within the third electronic component 53, to one of the two coils, while each electrode pad 532 is electrically connected, within the third electronic component 53, to the other of the two coils. The composition of each electrode pad 531, 532 is not particularly limited, but includes, for example, aluminum.

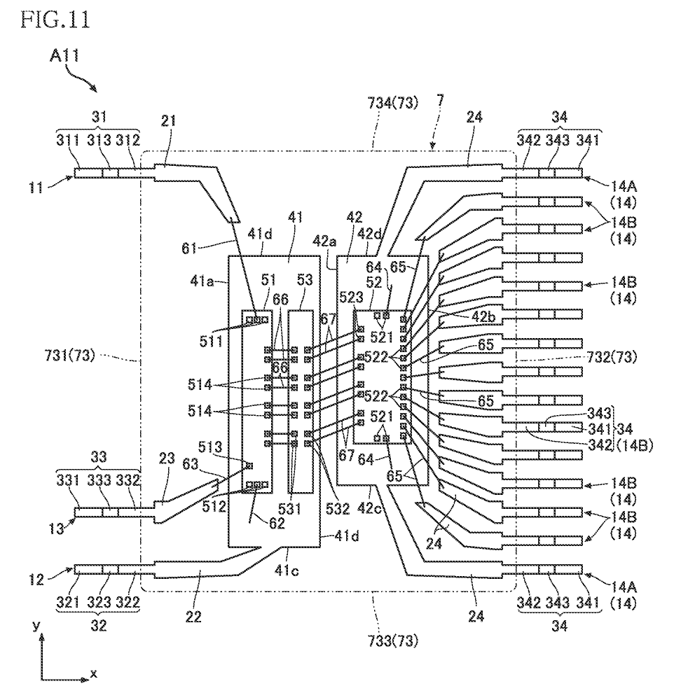

In the electronic device A10, the first electronic component 51, the second electronic component 52, and the third electronic component 53 have, for example, circuit configurations shown in FIG. 10. As shown in FIG. 10, the first electronic component 51 includes a voltage divider circuit 51A and an AD conversion circuit 51B, while the second electronic component 52 includes a DA conversion circuit 52A. The third electronic component 53 is, as previously described, an inductor-coupled isolation element (transformer). The voltage divider circuit 51A is an example of the “second circuit” recited in the claims, and the AD conversion circuit 51B is an example of the “first circuit” recited in the claims. The circuit configuration of the electronic device of the present disclosure is not limited to the example shown in FIG. 10 and may be modified in various ways.

The voltage divider circuit 51A divides the detection target voltage Vin and generates a voltage signal corresponding to the divided voltage of the voltage Vin. In the present embodiment, the voltage divider circuit 51A generates a voltage signal (the first signal) for detecting the potential difference between the potential of the first lead 11 and the potential of each second lead 12. In the present embodiment, the voltage divider circuit 51A divides the first voltage (i.e., voltage Vin) inputted to the first lead 11 and generates a voltage signal (first signal) corresponding to the first voltage. In the example shown in FIG. 10, the voltage divider circuit 51A includes four resistive elements or resistors R1 to R4. The voltage signal (the first signal mentioned above) is generated by the voltage division performed by the four resistive elements R1 to R4. The number of resistive elements is not limited to four. The four resistive elements R1 to R4 are connected in series. Specifically, one end of resistive element R1 is electrically connected to the electrode pad 511, and the other end of the resistive element R1 is electrically connected to one end of the resistive element R2. The other end of the resistive element R2 is electrically connected to one end of the resistive element R3, and the other end of the resistive element R3 is electrically connected to one end of the resistive element R4. The other end of resistive element R4 is electrically connected to the electrode pad 512. The connection point between the resistive element R3 and the resistive element R4 is connected to the AD conversion circuit 51B. Such a connection point to be connected to the AD conversion circuit 51B may be the connection point between the resistive element R1 and the resistive element R2, or the connection point between the resistive element R2 and the resistive element R3. For example, if the potential difference between the first lead 11 and the second lead(s) 12 (voltage Vin) is 800 V, and the resistance values of the four resistive elements R1 to R4 are the same, the potential at the connection point between the resistive element R1 and the resistive element R2 is 600 V, the potential at the connection point between the resistive element R2 and the resistive element R3 is 400 V, and the potential at the connection point between the resistive element R3 and the resistive element R4 is 200 V. Therefore, in light of the withstand voltage of the AD conversion circuit 51B, one of the connection points may be selected for connection to the circuit 51B.

The voltage divider circuit 51A divides the potential difference between the potential of the first lead 11 and the potential of the second leads 12 using the three resistive elements R1, R2, R3 and the resistive element R4, and outputs the divided voltage as a voltage signal (the first signal mentioned above) to the AD conversion circuit 51B. As such, the voltage divider circuit 51A does not require the supply of a power voltage when generating the voltage signal.

The AD conversion circuit 51B converts an analog voltage signal (first signal) from the voltage divider circuit 51A into a digital signal. In the example shown in FIG. 10, the AD conversion circuit 51B receives the voltage signal (first signal) as input from the connection point between the two resistive elements R3, R4 of the voltage divider circuit 51A. The AD conversion circuit 51B is connected to the electrode pad 513 and receives the power voltage VCC1 (approximately 5V to 24V, for example) from the electrode pad 513 (third lead 13). The AD conversion circuit 51B is supplied with the power voltage VCC1 for converting the analog signal into the digital signal. The AD conversion circuit 51B outputs the digitally-converted first signal to the second electronic component 52 via the third electronic component 53. The AD conversion circuit 51B is connected to one of the electrode pads 512 to be grounded to the reference potential GND1 via the electrode pad 512 (hence the second leads 12 electrically connected to the electrode pad 512).

The DA conversion circuit 52A converts the first signal inputted from the first electronic component 51 (AD conversion circuit 51B) into an analog signal via the third electronic component 53 and generates a voltage signal Vout (second signal). The DA conversion circuit 52A is connected to one electrode pad 522 and outputs the voltage signal Vout (second signal) from this electrode pad 522 (hence the signal lead 14B electrically connected to this electrode pad 522). Further, The DA conversion circuit 52A is supplied with power voltage VCC2 (e.g., approximately 5V to 24V) from another electrode pad 522 (hence the signal lead 14B electrically connected to the electrode pad 522). As such, the DA conversion circuit 52A is supplied with the power voltage VCC2 for converting digital signals to analog signals. After the analog conversion, the DA conversion circuit 52A outputs the second signal from one of the electrode pads 522 (hence the signal lead 14B electrically connected to the electrode pad 522). The DA conversion circuit 52A is connected to one electrode pad 521 and is grounded to the reference potential GND2 via the electrode pad 521 (hence the support lead 14A electrically connected to the electrode pad 521).

The connecting members 61 to 67 each electrically connect two separated locations to each other. In the illustrated example, the connecting members 61 to 67 are bonding wires. Alternatively, the connecting members 61 to 67 may be bonding ribbons or metal plates (metal clips). The connecting members 61 to 67 contain Au, Al or Cu, for example.

The connecting member 61 is bonded to an electrode pad 511 of the first electronic component 51 and to the first inner portion 21 of the first lead 11, as shown in FIG. 2. The connecting member 61 electrically connects the electrode pad 511 and the first inner portion 21 to each other. Thus, the first outer portion 31 of the first lead 11 is electrically connected to the first electronic component 51 via the connecting member 61.

The connecting member 62 is bonded to an electrode pad 512 of the first electronic component 51 and to the first die pad 41, as shown in FIG. 2. The connecting member 62 electrically connects the electrode pad 512 and the first die pad 41 to each other. Thus, the second outer portion 32 of each second lead 12 is electrically connected to the first electronic component 51 via the connecting member 62. The connecting member 62 may be bonded to the second inner portion 22 of one of the two second leads 12 instead of the first die pad 41.

The connecting member 63 is bonded to an electrode pad 513 of the first electronic component 51 and to the third inner portion 23 of the third lead 13, as shown in FIG. 2. The connecting member 63 electrically connects the electrode pad 513 and the third inner portion 23 to each other. Thus, the third outer portion 33 of the third lead 13 is electrically connected to the first electronic component 51 via the connecting member 63.

The two connecting members 64 are each bonded, as shown in FIG. 2, to an electrode pad 521 of the second electronic component 52 and to the second die pad 42. Each connecting member 64 electrically connects the electrode pad 521 and the second die pad 42 to each other. Thus, the fourth outer portion 34 of each support lead 14A is electrically connected to the second electronic component 52 via the two connecting members 64. Each connecting member 64 may be bonded to the fourth inner portion 24 of one of the two support leads 14A instead of the second die pad 42.

The connecting members 65 are each bonded, as shown in FIG. 2, to an electrode pad 522 of the second electronic component 52 and to the fourth inner portion 24 of one of the signal leads 14B. Each connecting member 65 electrically connects the electrode pad 522 and the fourth outer portion 34 of the signal lead 14B to each other. Thus, the fourth outer portion 34 of each signal lead 14B is electrically connected to the second electronic component 52 via the connecting members 65. In the example shown in FIG. 2, all the signal leads 14B are electrically connected to the electrode pads 522 by the connecting members 65. Alternatively, the number of the connecting members 65 may be reduced, and some signal leads 14B may not be electrically connected to the second electronic component 52.

The connecting members 66 are each bonded, as shown in FIG. 2, to an electrode pad 514 of the first electronic component 51 and to an electrode pad 531 of the third electronic component 53. Each connecting member 66 electrically connects the electrode pad 514 and the electrode pad 531 to each other. Thus, the first electronic component 51 and the third electronic component 53 are electrically connected to each other via the connecting members 66.

The connecting members 67 are each bonded to an electrode pad 523 of the second electronic component 52 and an electrode pad 532 of the third electronic component 53, as shown in FIG. 2. Each connecting member 67 electrically connects the electrode pad 523 and the electrode pad 532 to each other. Thus, the second electronic component 52 and the third electronic component 53 are electrically connected via the connecting members 67.

The sealing resin 7 covers the first electronic component 51 and the second electronic component 52. The sealing resin 7 covers the third electronic component 53. The sealing resin 7 covers portions of the respective leads, i.e., the first lead 11, the two second leads 12, the third lead 13, and the fourth leads 14 (two support leads 14A and signal leads 14B). The sealing resin 7 covers the first die pad 41 and the second die pad 42. The sealing resin 7 covers the connecting members 61 to 67. The sealing resin 7 may be made of, for example, an insulating material such as an epoxy resin. Preferably, the sealing resin 7 may be made of a resin material having a Comparative Tracking Index (CTI) of 600V or higher. The sealing resin 7 has, for example, a rectangular prism shape. The sealing resin 7 has a dimension along the first direction x of, for example, not less than 5 mm and not more than 10 mm, and a dimension along the second direction y of, for example, not less than 3 mm and not more than 13 mm. The dimensions of the sealing resin 7 along the first direction x and the second direction y are not limited to these examples. The sealing resin 7 has a resin obverse surface 71, a resin reverse surface 72, and a plurality of resin side surfaces 73.

The resin obverse surface 71 and the resin reverse surface 72 are spaced apart from each other in the thickness direction z. The resin obverse surface 71 faces one side (the upper side) in the thickness direction z, and the resin reverse surface 72 faces the other side (the lower side) in the thickness direction z. The resin obverse surface 71 is the upper surface of the sealing resin 7, and the resin reverse surface 72 is the lower surface of the sealing resin 7.

The resin side surfaces 73 are arranged to face their respective orthogonal directions perpendicular to the thickness direction z, where these orthogonal directions may include a first direction x and a second direction y. The resin side surfaces 73 are interposed between the resin obverse surface 71 and the resin reverse surface 72 in the thickness direction z and are connected thereto. In the illustrated example, the resin side surfaces 73 include a first resin side surface 731, a second resin side surface 732, a third resin side surface 733, and a fourth resin side surface 734.

The first resin side surface 731 and the second resin side surface 732 are spaced apart from each other in the first direction x. The first resin side surface 731 faces one side in the first direction x, and the second resin side surface 732 faces the other side in the first direction x. The third resin side surface 733 and the fourth resin side surface 734 are spaced apart from each other in the second direction y. The third resin side surface 733 faces one side in the second direction y, and the fourth resin side surface 734 faces the other side in the second direction y.

As shown in FIGS. 1 and 2, in the electronic device A10, the first outer portion 31 of the first lead 11, the second outer portions 32 of the two second leads 12, and the third outer portion 33 of the third lead 13 protrude from the first resin side surface 731. In the electronic device A10, as shown in FIG. 2, the first lead 11, the third lead 13, and the two second leads 12 are arranged in this order along the first resin side surface 731 or in the second direction y, from the fourth resin side surface 734 toward the third resin side surface 733. Alternatively, the first lead 11, the third lead 13, and the two second leads 12 may be arranged in this order along the first resin side surface 731 in the second direction y from the third resin side surface 733 toward the fourth resin side surface 734. As shown in FIGS. 1 and 2, the fourth outer portions 34 of the fourth leads 14 (two support leads 14A and signal leads 14B) protrude from the second resin side surface 732. In the electronic device A10, as shown in FIG. 2, one of the two support leads 14A, the signal leads 14B, and the other of the two support leads 14A are arranged in this order along the second resin side surface 732 in the second direction y from the fourth resin side surface 734 toward the third resin side surface 733.

The electronic device A10 may have the following workings and advantages. In the electronic device A10, the first outer portion 31 of the first lead 11, the second outer portions 32 of the second leads 12, and the third outer portion 33 of the third lead 13, which are electrically connected to the first electronic component 51, protrude from one resin side surface 73 of the sealing resin 7, while the the fourth outer portion 34 of the fourth leads 14 electrically connected to the second electronic component 52 protrudes from another or different resin side surface 73 of the sealing resin 7. With this configuration, the creepage distance (distance along the resin side surface(s) 73) between a group of the first outer portion 31, the second outer portion 32 and the third outer portion 33 and a group of the fourth outer portions 34 can be large. Therefore, even when the voltage difference between the first electronic component 51 and the second electronic component 52 is large, discharge is less likely to occur between the group of the first outer portion 31, the second outer portion 32 and the third outer portion 33 and the group of the fourth outer portions 34. As such, the electronic device A10 can suppress discharge between the group of the first outer portion 31, the second outer portion 32 and the third outer portion 33 and the group of the fourth outer portions 34, while also achieving the size reduction. In other words, the electronic device A10 has an advantages package structure for suppressing discharge between the first, second, third leads 11, 12, 13 and the fourth leads 14.

In the electronic device A10, the first outer portion 31 of the first lead 11 and the second outer portion 32 of the inner one of the second leads 12 are arranged in the second direction y with a distance d12 between them. The fourth outer portions 34 of the fourth leads 14 are arranged in the second direction y with either a distance d42 or a distance d44 between them. The distance d12 is greater than each of the distances d42 and d44. With this configuration, the creepage distance between the first outer portion 31 and the second outer portion 32 is greater than the creepage distance between the fourth outer portions 34. Therefore, even when a high voltage is applied between the first outer portion 31 and the second outer portion 32, discharge is less likely to occur between them. Therefore, the electronic device A10 enables suppression of discharge between the first outer portion 31 and the second outer portion 32 while achieving the size reduction of the device. As such, the electronic device A10 has a preferred package structure for suppressing discharge between the first outer portion 31 and the second outer portion 32.

In the electronic device A10, the third outer portion 33 of the third lead 13 is disposed between the first outer portion 31 of the first lead 11 and the two second outer portions 32 of the respective second leads 12. According to this configuration, the third outer portion 33, which can have a potential between the potential of the first outer portion 31 and the potential of the two second outer portions 32, allows the distance, along the second direction y, between the first outer portion 31 and one of the two second outer portions 32 (which is closer to the first outer portion 31) to be made greater. In particular, since the third outer portion 33 is closer to the two second outer portions 32 than to the first outer portion 31, it is advantageous for suppressing discharge among the first outer portion 31, the two second outer portions 32, and the third outer portion 33. In the electronic device A10, the first outer portion 31, the two second outer portions 32 and the third outer portion 33 are exposed to protrude from the first resin side surface 731, while the fourth outer portions 34 are exposed to protrude from the second resin side surface 732. With this configuration, the creepage distance between the group of the first outer portion 31, the two second outer portions 32 and the third outer portion 33 and the group of the fourth outer portions 34 along the sealing resin 7 can be at least a creepage distance along the third resin side surface 733 (or the fourth resin side surface 734). As such, the electronic device A10 has a preferred package structure for suppressing discharge between the group of the first outer portion 31, the two second outer portions 32 and the third outer portion 33 and the group of the fourth outer portions 34.

Other embodiments and variations of the electronic device according to the present disclosure are described below. The elements used in the following embodiments and/or variations can be appropriately combined with one another as long as no technical conflicts arise.

FIG. 11 shows an electronic device A11 according to a variation of the first embodiment. The electronic device A11 may differ from the electronic device A10 in that the connection position of the second inner portion 22 of the second lead 12 with the first die pad 41 is different. In the example shown in FIG. 11, the electronic device A11 has only one second lead 12. Alternatively, the electronic device A11 may have two second leads 12, like the electronic device A10, or may have more than two second leads 12.

In the illustrated electronic device A11, the second inner portion 22 is connected at the center of the edge 41c of the first die pad 41 in the first direction x. The connection position of the second inner portion 22 may be at any other point on the edge 41c and is not limited to the center in the first direction x.

The electronic device A11 can enjoy the same advantages as those of the electronic device A10. As understood from the present variation, the second inner portion 22 is not limited to being connected to a corner of the first die pad 41 (e.g., the corner formed by the two edges 41a, 41c) but may be connected to a point along the edge 41c.

### SECOND EMBODIMENT:

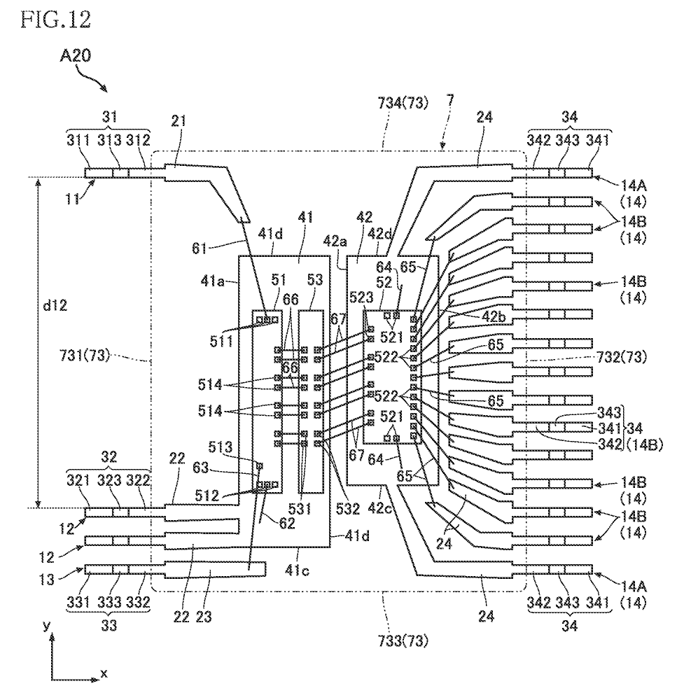

FIG. 12 shows an electronic device A20 according to a second embodiment. The electronic device A20 may differ from the electronic device A10 in that the third lead 13 (third outer portion 33) of the electronic device A20 is disposed outward of the two second leads 12 (two second outer portions 32) in the second direction y.

In the electronic device A20, as shown in FIG. 12, the third outer portion 33 of the third lead 13 is disposed closer to the third resin side surface 733 in the second direction y than are the third inner portions 23 of the two second leads 12. In the illustrated example, the third outer portion 33 (third root portion 332) of the third lead 13 does not overlap with the first die pad 41 as viewed in the first direction x. Alternatively, the third outer portion 33 (third root portion 332) may overlap with the first die pad 41. In the illustrated example, the third inner portion 23 of the third lead 13 is long enough to have a portion that overlaps with the first die pad 41 as viewed in the second direction y. Alternatively, the third inner portion 23 may not overlap with the first die pad 41 as viewed in the second direction y by having a shortened length.

In the example shown in FIG. 12, the second inner portion 22 of one second lead 12 connects to a corner of the first die pad 41 formed by two edges 41a, 41c, while the second inner portion 22 of the other second lead 12 connects to the edge 41a of the first die pad 41. In the illustrated example, the second outer portions 32 (and hence, e.g., the second root portions 322) of the two second leads 12 overlap with the first die pad 41 as viewed in the first direction x.

In the electronic device A20, as in the electronic device A10, the resin side surface 73 from which the first outer portion 31, the second outer portions 32 and the third outer portion 33 are exposed is different from the resin side surface 73 from which the fourth outer portions 34 are exposed. Thus, the electronic device A20, like electronic device A10, can suppress the occurrence of discharge between the group of the first outer portion 31, the second outer portions 32 and the third outer portion 33 and the group of the fourth outer portions 34. Consequently, it is possible to achieve the size reduction of the device while also suppressing discharge between the exposed portions. As such, the electronic device A20 has a preferred package structure for suppressing discharge between the group of the first outer portion 31, the second outer portions 32 and the third outer portion 33 and the group of the fourth outer portions 34. The electronic device A20 can enjoy the same advantages as those of the electronic devices A10 and A11 by having common configurations.

As understood from the electronic device A20, the third lead 13 may be disposed outward or inward of at least one second lead 12 in the second direction y. However, considering that the potential difference between the first lead 11 and the second lead(s) 12 is greater than the potential difference between the first lead 11 and the third lead 13, the electronic device A10 may be preferable over the electronic device A20 because the former is suitable for having a greater creepage distance along the first resin side surface 731 between the first lead 11 (first outer portion 31) and the the second lead 12 (second outer portion 32), in other words, for suppressing discharge between the first outer portion 31 and the second outer portion(s) 32.

### THIRD EMBODIMENT:

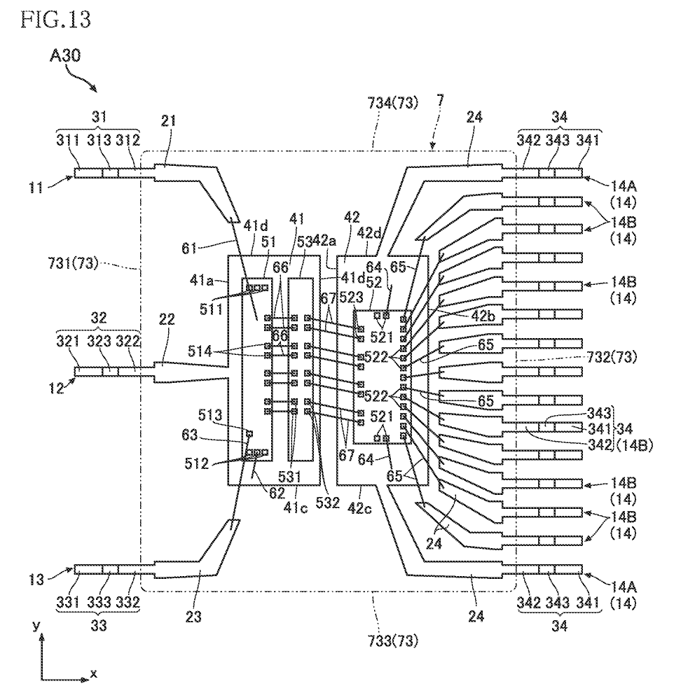

FIG. 13 shows an electronic device A30 according to a third embodiment. The electronic device A30 may differ from the electronic device A10 in that the second lead 12 is connected to the first die pad 41 at a different location. In the example shown in FIG. 13, the electronic device A30 has only one second lead 12.

In the electronic device A30, the second inner portion 22 of the second lead 12 is connected to the center of the edge 41a of the first die pad 41. In other words, the second inner portion 22 is connected at the center of the edge of the first die pad 41 that extends in the second direction y, and that is located on one side in the first direction x (the side closer to the first resin side surface 731). The second inner portion 22 extends along the first direction x from the first die pad 41.

In the electronic device A30, as with the electronic device A10, the group of the first outer portion 31, the second outer portion 32 and the third outer portion 33 are exposed from one resin side surface 73 of the sealing resin 71, while the group of the fourth outer portions 34 are exposed from another resin side surface 73. Thus, the electronic device A30, like the electronic device A10, can suppress the occurrence of discharge between the group of the first outer portion 31, the second outer portion 32 and the third outer portion 33 and the group of the fourth outer portion 34, which enables the size reduction of the device. As such, the electronic device A30 has a preferred package structure for suppressing discharge between the group of the first outer portion 31, the second outer portion 32 and the third outer portion 33 and the group of the fourth outer portions 34. The electronic device A30 can enjoy the same advantages as those of the electronic devices A10, A11 and A20 by having common configurations.

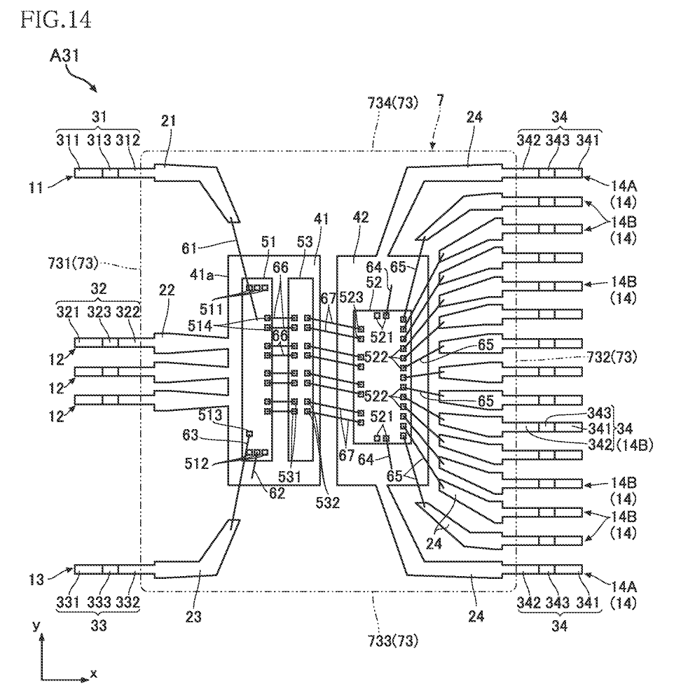

FIG. 14 shows an electronic device A31 according to a first variation of the third embodiment. The electronic device A31 may differ from the electronic device A30 in the number of second leads 12. In the illustrated example, the electronic device A31 has three second leads 12.

In the electronic device A31, the second inner portions 22 of the three second leads 12 connect to the edge 41a of the first die pad 41. The second outer portions 32 of the three second leads 12 protrude from a central region of the first resin side surface 731 in the second direction y and are spaced apart from each other in the second direction y. The signal leads 14B include three fourth outer portions 34 located in a central region in the second direction y. These three fourth outer portions 34 are substantially aligned, along the first direction x, with the three second outer portions 32, respectively.

The electronic device A31 can enjoy the same advantages as those of the electronic device A30. As understood from electronic device A31, the number of second leads 12 for the electronic device of the present disclosure is not particularly limited.

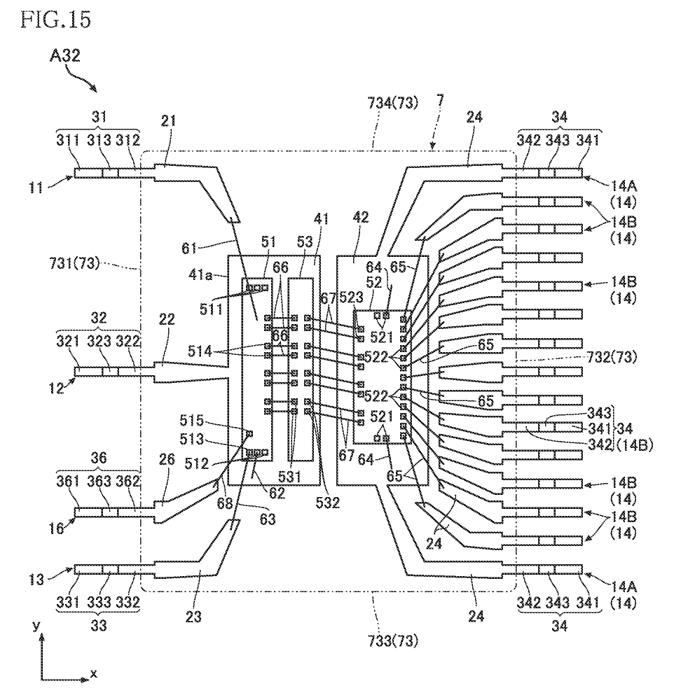

FIG. 15 shows an electronic device A32 according to a second variation of the third embodiment. The electronic device A32 may differ from the electronic device A30 in that the electronic device A32 includes a sixth lead 16.

The sixth lead 16 may receive input of a second voltage from the circuit board with the electronic device A32 mounted thereon. The second voltage may have a value different from the first voltage (voltage Vin) inputted to the first lead 11, the ground voltage inputted to the second lead 12, and the power voltage VCC1 inputted to the third lead 13. The second voltage is not particularly limited, but may be, for example, a negative voltage (e.g., -800V) corresponding to the first voltage, or a negative power voltage (e.g., -5V to -24V) corresponding to the power voltage VCC1.

The sixth lead 16 includes a sixth inner portion 26 and a sixth outer portion 36. The sixth inner portion 26 and the sixth outer portion 36 are connected to each other to form a single piece. The boundary between the sixth inner portion 26 and the sixth outer portion 36 overlaps with the periphery of the sealing resin 7 in plan view.

The sixth inner portion 26 is the part of the sixth lead 16 covered by the sealing resin 7. The sixth inner portion 26 connects to the sixth outer portion 36 and extends inward from the sixth outer portion 36 into the sealing resin 7. The sixth inner portion 26 may be disposed closer to the first resin side surface 731 than to the first die pad 41 in the first direction x. The sixth inner portion 26 is spaced apart from the first die pad 41.

The sixth outer portion 36 is the part of the sixth lead 16 that is exposed from the sealing resin 7. In the present embodiment, the sixth outer portion 36 protrudes in the first direction x from the sealing resin 7 (first resin side surface 731) in plan view. The sixth outer portion 36 has a rectangular shape with longer sides extending in the first direction x in plan view. The sixth outer portion 36 is curved in a gull-wing shape as viewed in the second direction y. The width of the sixth outer portion 36 (the dimension in the second direction y in the illustrated example) is not particularly limited but is, for example, the same as the width W11 of the first outer portion 31, the width W12 of the second outer portion 32, the width W13 of the third outer portion 33, and the widths W141, W142 of the fourth outer portion 34. The sixth outer portion 36 includes a sixth mounting portion 361, a sixth root portion 362, and a sixth intermediate portion 363.

The sixth mounting portion 361 is a tip portion of the sixth outer portion 36. The sixth mounting portion 361 is the part that is bonded to the circuit board when mounting the electronic device A32 onto the circuit board. As shown in FIG. 15, the sixth mounting portion 361 is located at the end opposite from the sealing resin 7 in the first direction x. Thus, the sixth mounting portion 361 is disposed farther from the sealing resin 7 in the first direction x than are the sixth root portion 362 and the sixth intermediate portion 363. The sixth mounting portion 361 is disposed lower in the thickness direction z than is the sixth root portion 362.

The sixth root portion 362 is the proximal part of the sixth outer portion 36. As shown in FIG. 15, the sixth root portion 362 is located at the end of the sixth outer portion 36 closer to the sealing resin 7 in the first direction x. Thus, the sixth root portion 362 is disposed closer to the sealing resin 7 in the first direction x than are the sixth mounting portion 361 and the sixth intermediate portion 363. The sixth root portion 362 is disposed above the sixth mounting portion 361 in the thickness direction z and protrudes from a central region of the sealing resin 7 in the thickness direction z.

The sixth intermediate portion 363 connects the sixth mounting portion 361 and the sixth root portion 362 to each other. The sixth intermediate portion 363 is inclined relative to the sixth mounting portion 361 and the sixth root portion 362 as viewed in the second direction y. In the present embodiment, the sixth intermediate portion 363 is inclined relative to the thickness direction z.

In the electronic device A32, as shown in FIG. 15, the first electronic component 51 has an electrode pad 515. In the illustrated example, use is made of only one electrode pad 515. Alternatively, more than one electrode pad 515 may be provided. The electrode pad 515 is disposed on the upper surface (the surface facing upward in the thickness direction z) of the first electronic component 51, as with the other electrode pads 511 to 514. The composition of the electrode pad 515 is not particularly limited, but may, for example, contain aluminum like the other electrode pads 511 to 514. The electrode pad 515 is an input member for the second voltage.

The electronic device A32 includes a connecting member 68. The connecting member 68 may be a bonding wire, as are the other connecting members 61 to 67, but it may be a bonding ribbon or a metal plate (metal clip) instead of a bonding wire. The connecting member 68 contains Au, Al (aluminum), or Cu, as in the other connecting members 61 to 67. As shown in FIG. 15, the connecting member 68 is bonded to the sixth inner portion 26 of the sixth lead 16 and to the electrode pad 515 of the first electronic component 51, thereby electrically connecting them.

The electronic device A32 can enjoy the same advantages as those of the electronic device A30. The electronic device A32 includes the sixth lead 16. Thus, it is possible to input not only a first voltage but also a second voltage to the first electronic component 51. As understood from this, the electronic device of the present disclosure may be configured to enable inputting a first voltage and a second voltage (which is e.g., polarity-reversed first voltage or polarity-reversed power voltage VCC1) to the first electronic component 51.

### FOURTH EMBODIMENT:

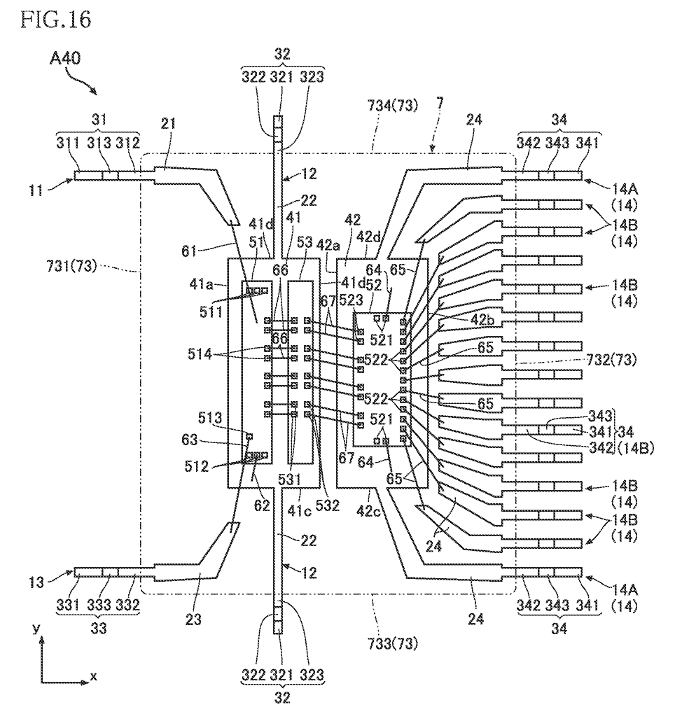

FIG. 16 shows an electronic device A40 according to a fourth embodiment. The electronic device A40 may differ from the electronic device A10 in that two second leads 12 are exposed from either the third resin side surface 733 or the fourth resin side surface 734. In the illustrated example, the two second leads 12 are individually exposed from the third resin side surface 733 and the fourth resin side surface 734, respectively.

In the electronic device A40, the second inner portion 22 of one second lead 12 is connected to the center of the edge 41c of the first die pad 41 (the edge close to the third resin side surface 733 in the second direction y and extending in the first direction x). while the second inner portion 22 of the other second lead 12 is connected to the edge 41d of the first die pad 41 (the edge close to the fourth resin side surface 734 in the second direction y and extending in the first direction x). Each second inner portion 22 extends from the first die pad 41 along the second direction y. The second outer portion 32 of one second lead 12 is exposed from the third resin side surface 733, and the second outer portion 32 of the other second lead 12 is exposed from the fourth resin side surface 734. In the illustrated example, the two second leads 12 protrude from the third resin side surface 733 or the fourth resin side surface 734 and are bent in a gull-wing shape.

In the electronic device A40, as with the electronic device A10, the resin side surface 73 from which the first outer portion 31, the second outer portion 32 and the third outer portion 33 are exposed is different from the resin side surface 73 from which the fourth outer portions 34 are exposed. Therefore, the electronic device A40, like the electronic device A10, can suppress the occurrence of discharge between the group of the first outer portion 31, the second outer portion 32 and the third outer portion 33 and the group of the fourth outer portions 34. This enables discharge suppression while achieving the size reduction of the device. As such, the electronic device A40 has a preferred package structure for suppressing discharge between the first, second, and third outer portions 31, 32, 33 and the fourth outer portions 34. The electronic device A40, by having common configurations with the other electronic devices A10, A11, A20, A30 to A32, can enjoy the same advantages as those of the electronic devices A10, A11, A20, A30 to A32.

As understood from the electronic device A40, the electronic device of the present disclosure is not limited to an example where the second lead 12 connected to the first die pad 41 is exposed from the first resin side surface 731. The second lead 12 may be exposed from the third resin side surface 733 or the fourth resin side surface 734.

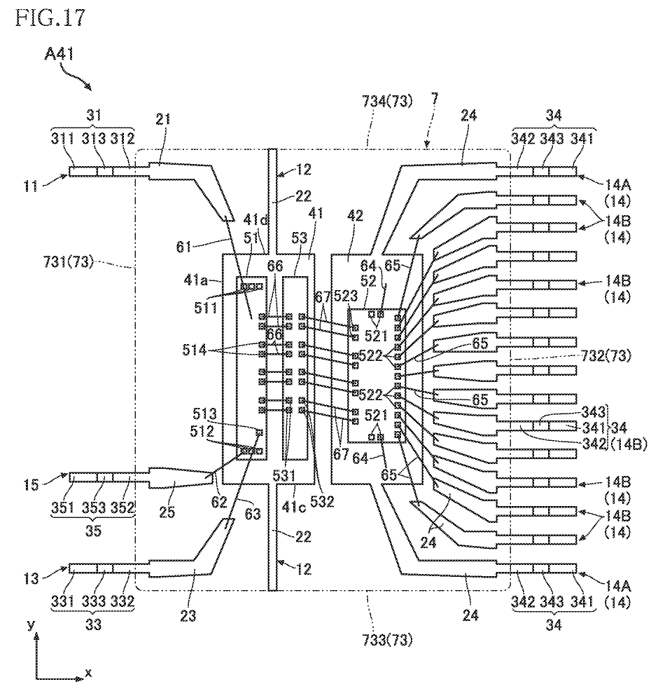

FIG. 17 shows an electronic device A41 according to a first variation of the fourth embodiment. The electronic device A41 may differ from the electronic device A40 in that the electronic device A41 includes a fifth lead 15.

The fifth lead 15, though spaced apart from the first die pad 41, has the same potential as that of the first die pad 41. Hence, the fifth lead 15 has the same potential as that of the second lead 12.

The fifth lead 15 includes a fifth inner portion 25 and a fifth outer portion 35. The fifth inner portion 25 and the fifth outer portion 35 are connected to each other to form a single piece. The boundary between the fifth inner portion 25 and the fifth outer portion 35 overlaps with the periphery of the sealing resin 7 in plan view.

The fifth inner portion 25 is the part of the fifth lead 15 covered by the sealing resin 7. The fifth inner portion 25 connects to the fifth outer portion 35 and extends inward from the fifth outer portion 35 within the sealing resin 7. The fifth inner portion 25 is disposed closer to the first resin side surface 731 than to the first die pad 41 in the first direction x. The fifth inner portion 25 is spaced apart from the first die pad 41. A connecting member 62 is bonded to the fifth inner portion 25. The fifth inner portion 25 is electrically connected to an electrode pad 512 of the first electronic component 51 via the connecting member 62.

The fifth outer portion 35 is the part of the fifth lead 15 that is exposed from the sealing resin 7. In the present embodiment, the fifth outer portion 35 protrudes in the first direction x from the sealing resin 7 (first resin side surface 731) in plan view. The fifth outer portion 35 has a rectangular shape with longer sides extending in the first direction x in plan view. The fifth outer portion 35 is curved in a gull-wing shape as viewed in the second direction y. The width of the fifth outer portion 35 (the dimension in the second direction y) is not particularly limited, but is, for example, the same as the width W11 of the first outer portion 31, the width W12 of the second outer portion 32, the width W13 of the third outer portion 33, and the widths W141, W142 of the fourth outer portion 34. The fifth outer portion 35 includes a fifth mounting portion 351, a fifth root portion 352, and a fifth intermediate portion 353.

The fifth mounting portion 351 is a tip portion of the fifth outer portion 35. The fifth mounting portion 351 is the part that is bonded to the circuit board when mounting the electronic device A41 onto the circuit board. As shown in FIG. 17, the fifth mounting portion 351 is located at the end opposite from the sealing resin 7 in the first direction x. Therefore, in the first direction x, the fifth mounting portion 351 is disposed farther from the sealing resin 7 than are the fifth root portion 352 and the fifth intermediate portion 353. The fifth mounting portion 351 is disposed lower in the thickness direction z than the fifth root portion 352.

The fifth root portion 352 is the proximal part of the fifth outer portion 35. As shown in FIG. 17, the fifth root portion 352 is located at one of the ends of the fifth outer portion 35 that is closer to the sealing resin 7 in the first direction x. Therefore, in the first direction x, the fifth root portion 352 is disposed closer to the sealing resin 7 than are the fifth mounting portion 351 and the fifth intermediate portion 353. The fifth root portion 352 is disposed above the fifth mounting portion 351 in the thickness direction z and protrudes from the central region of the sealing resin 7 in the thickness direction z.

The fifth intermediate portion 353 connects the fifth mounting portion 351 and the fifth root portion 352 to each other. For example, the fifth intermediate portion 353 is inclined relative to the fifth mounting portion 351 and the fifth root portion 352 as viewed in the second direction y. In the present embodiment, the fifth intermediate portion 353 is inclined relative to the thickness direction z.

The electronic device A41 can enjoy the same advantages as those of the electronic device A40. In the electronic device A41, the fifth lead 15 serves as the input terminal for the reference potential GND1. According to this configuration, the second lead 12 need not protrude from the sealing resin 7 in plan view. Therefore, electronic device A41 can reduce its dimension in the second direction y compared to the electronic device A40.

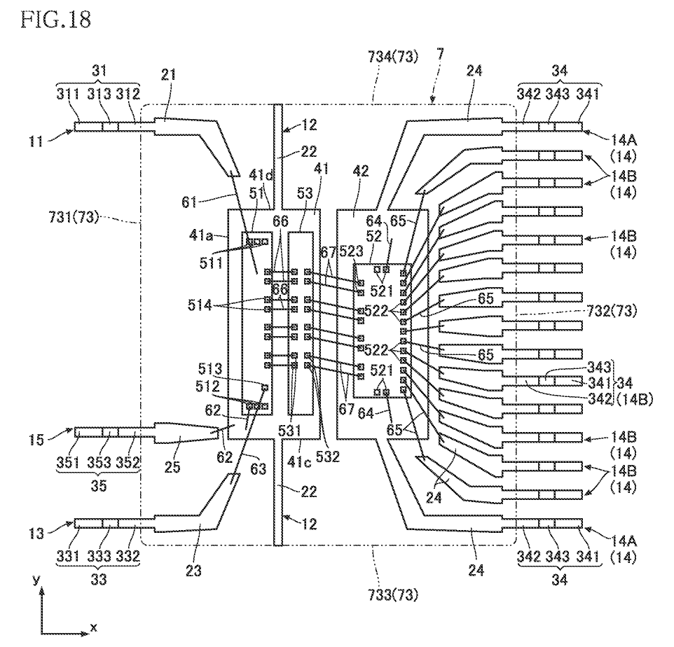

Differing from the electronic device A41, the electronic device of the present disclosure, as shown in FIG. 18, may comprise two connecting members 62. One of the two connecting members 62 may electrically connect the first die pad 41 and the fifth inner portion 25 to each other, while the other connecting member 62 may electrically connect the electrode pad 512 of the first electronic component 51 and the first die pad 41 to each other. When the electrode pad 512 is disposed on the reverse surface (facing downward in the thickness direction z) of the first electronic component 51, and the first die pad 41 and the electrode pad 512 are electrically connected by a conductive bonding material for bonding of the first electronic component 51, the connecting member 62 may not be provided. Still with this configuration, the fifth lead 15 is at the same potential as the second lead 12. This allows for the size reduction of the device in the second dimension y while also ensuring the provision of a ground terminal (the terminal to be at the reference potential GND1).

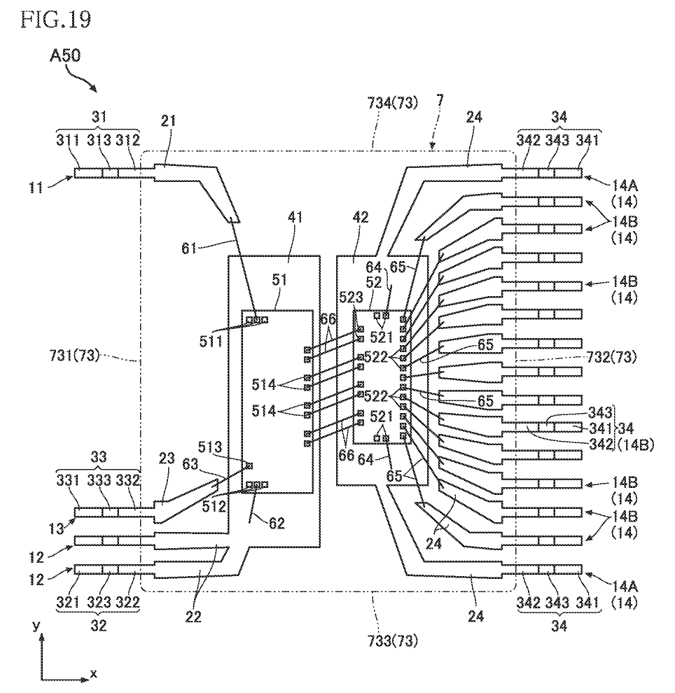

FIGS. 19 to 28 show other examples of the electronic device of the present disclosure. The configurations shown in FIGS. 19 to 28 may be applied to the above-noted first embodiment to fourth embodiment (including variations thereof). The electronic devices shown in FIGS. 19 to FIG. 28 can enjoy the same advantages as those of the electronic device A10.

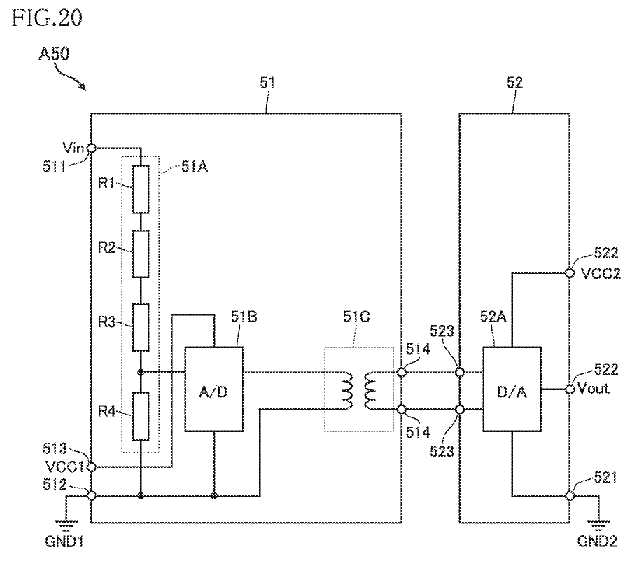

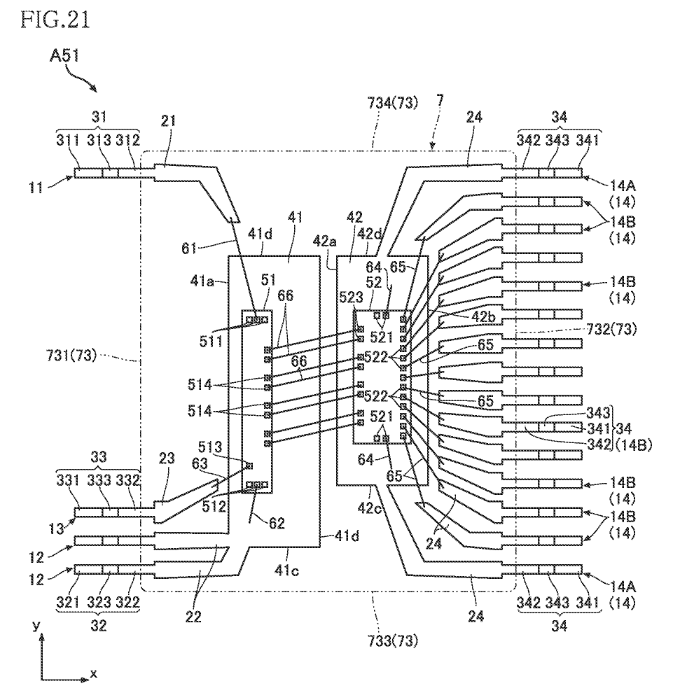

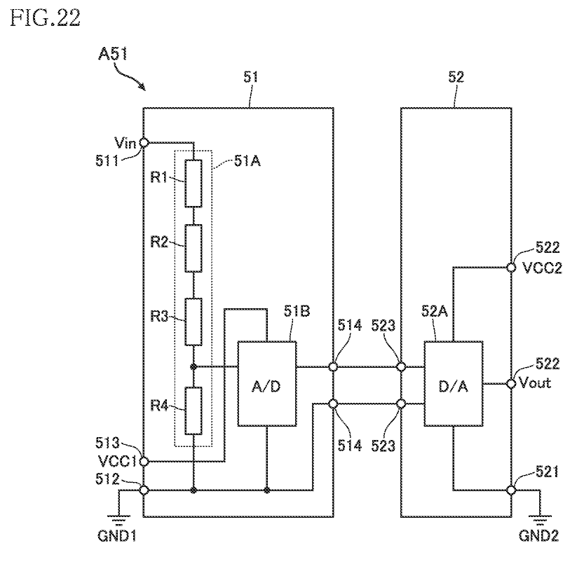

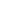

The electronic device of the present disclosure may not include a third electronic component 53 and may include a first electronic component 51 and a second electronic component 52. For example, the electronic device of the present disclosure may have functions equivalent to those of the third electronic component 53 that are incorporated within the first electronic component 51, as seen from the electronic device A50 in FIG. 19 and FIG. 20. In the electronic device A50, as shown in FIG. 20, the first electronic component 51 includes an insulated transmission circuit 51C corresponding to the function of the third electronic component 53. The insulated transmission circuit 51C is connected internally within the first electronic component 51 to the AD conversion circuit 51B. The electrode pads 514 of the first electronic component 51 are electrically connected to the output of the insulated transmission circuit 51C. In the electronic device A50, the connecting members 66 electrically connect electrode pads 514 of the first electronic component 51 to electrode pads 523 of the second electronic component 52. As an example differing from the electronic device A50, the electronic device of the present disclosure may not necessarily include the functional configurations of the third electronic component 53, as with the electronic device A51 shown in FIG. 21 and FIG. 22. In the electronic device A51, as seen from FIG. 22, the AD conversion circuit 51B of the first electronic component 51 is electrically connected to the DA conversion circuit 52A of the second electronic component 52 without passing through the third electronic component 53 or the insulated transmission circuit 51C.

In the electronic device of the present disclosure, the third electronic component 53 may be mounted on the second die pad 42 instead of the first die pad 41. For example, as with the electronic device A52 shown in FIG. 23, the third electronic component 53 may be bonded to the second die pad 42 together with the second electronic component 52.

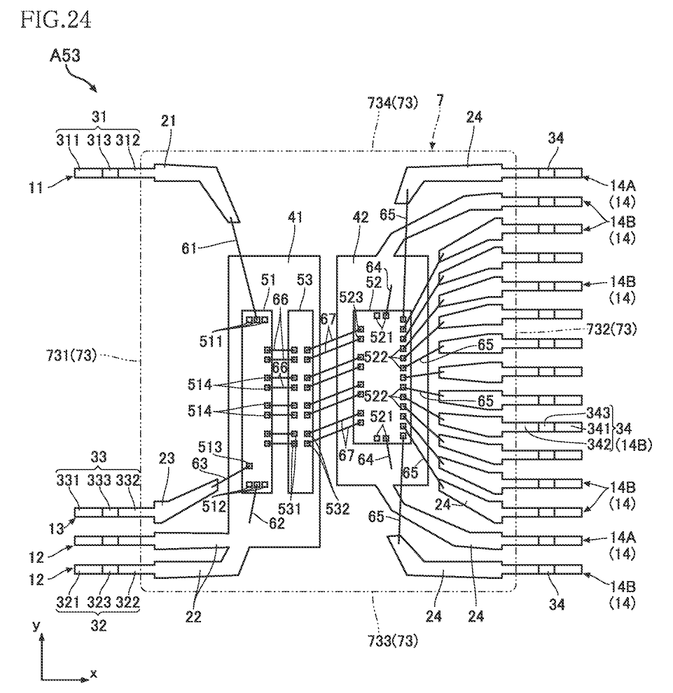

In the electronic device of the present disclosure, the number and positioning of the support leads 14A and signal leads 14B of the fourth leads 14 are not particularly limited. For example, the electronic device of the present disclosure may have one or more signal leads 14B arranged outside two support leads 14A in the second direction y, as with the electronic device A53 shown in FIG. 24. In the electronic device A53, as shown in FIG. 24, one signal lead 14B is disposed outward of each support lead 14A in the second direction y.

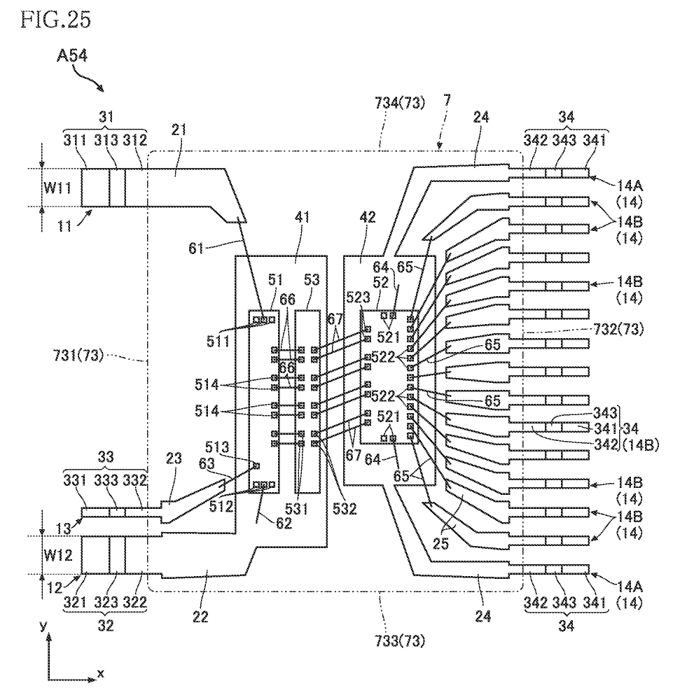

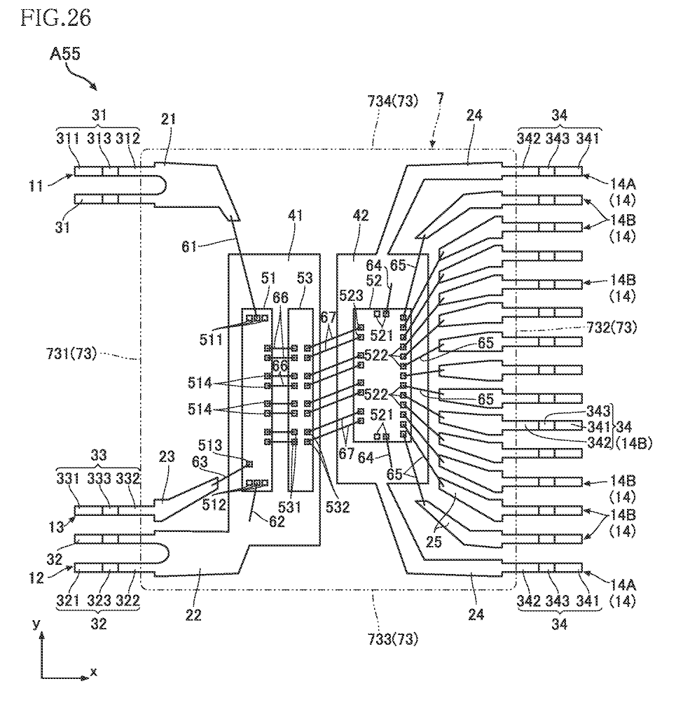

In the electronic device of the present disclosure, the configurations (size, shape, number, etc.) of the first lead(s) 11 and the configurations (size, shape, number, etc.) of the second lead(s) 12 are not limited to the illustrated examples. In the electronic device of the present disclosure, as with the electronic device A54 shown in FIG. 25, the width W11 of the first outer portion 31 of the first lead 11 and the width W12 of the second outer portion 32 of the second lead 12 may be greater than the widths W141 and W142 of the fourth outer portions 34 of the fourth leads 14. Alternatively, differing from the electronic device A54, the electronic device of the present disclosure may, as with the electronic device A55 shown in FIG. 26, have a plurality (two in the illustrated example) of first outer portions 31 connected to a single first inner portion 21, and have a plurality (two in the illustrated example) of second outer portions 32 connected to a single second inner portion 22. The examples shown in FIGS. 25 and 26 illustrate cases where the third lead 13 is configured similarly to that of the electronic device A10. For the third lead 13, the width of the third outer portion 33 may be greater as with the first lead 11 and the second lead 12. A plurality of third outer portions 33 may be connected to a single third inner portion 23.

According to the above variations, the electronic devices A54 and A55 can be prevented from detaching from the circuit board once mounted, thereby improving the device's mounting reliability. For example, thermal stress may be applied to the mounting portion (soldered area) of the electronic devices A54 and A55 on the circuit board due to power supply to the circuit board. Thermal stress can concentrate on a smaller number of leads when the number of leads protruding from the first resin side surface 731 differs from the number of leads protruding from the second resin side surface 732. In the case of the electronic devices A54 and A55, thermal stress may concentrate on the first lead 11 and the second lead 12, for example. In view of this, for the electronic device A54, the width W11 of the first outer portion 31 of the first lead 11 and the width W12 of the second outer portion 32 of the second lead 12 are made great enough to enhance the bonding strength to the circuit board. This suppresses detachment of the device from the circuit board. In the electronic device A55, on the other hand, it is arranged that the first lead 11 includes two first outer portions 31 and the second lead 12 includes two second outer portions 32 so that the thermal stress related to the first and second outer portions 31, 32 is dispersed. This suppresses detachment of the device from the circuit board.

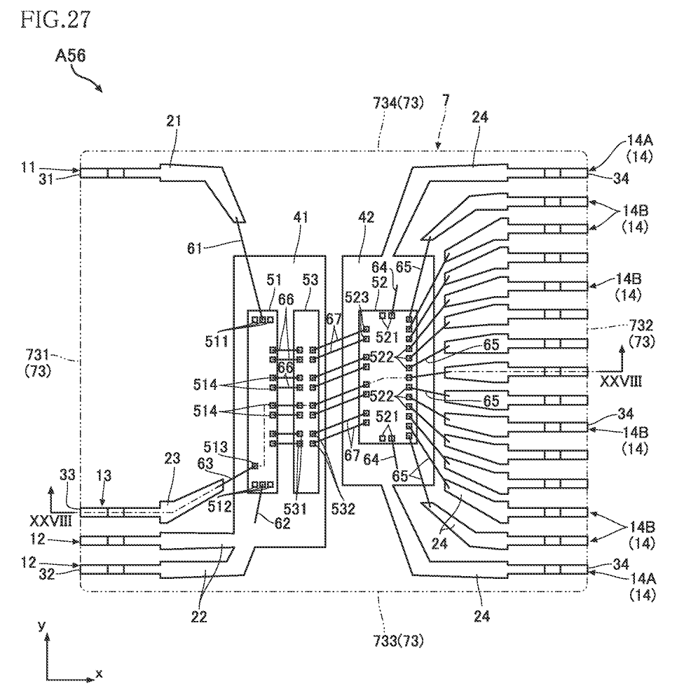

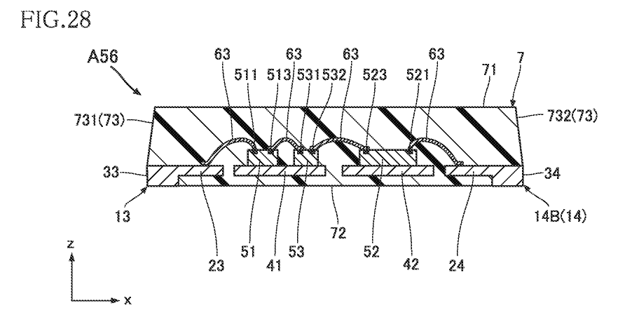

The package structure of the electronic device of the present disclosure is not limited to the SOP type and may adopt other types. For example, the electronic device of the present disclosure may have a non-lead type package structure, as with the electronic device A56 shown in FIG. 27 and FIG. 28. In the electronic device A56, as shown in FIG. 27, the first lead 11, the two second leads 12, the third lead 13 and the fourth leads 14 do not protrude from the sealing resin 7 in plan view. As seen from FIG. 28, the end faces of the first lead 11, the second leads 12, the third lead 13 and the fourth leads 14 are flush with the relevant resin side surface 73 (i.e., the first resin side surface 731 or the second resin side surface 732). In this example, the end faces of the first outer portion 31 of the first lead 11, the second outer portions 32 of the second leads 12, the third outer portion 33 of the third lead 13 and the fourth outer portions 34 of the fourth leads 14 are not covered, but exposed from the respective resin side surfaces 73 (the first resin side surface 731 or the second resin side surface 732). As understood from FIG. 28, the first inner portion 21 of the first lead 11, the second inner portions 22 of the second leads 12 and the third inner portion 23 of the third lead 13 have respective end portions that are relatively thick (with a greater dimension in the thickness direction z) near the first resin side surface 731. Likewise, the fourth inner portions 24 of the fourth leads 14 have respective end portions that are relatively thick near the second resin side surface 732. With such configurations, the lower surfaces of the first die pad 41 and second die pad 42 are not exposed from the sealing resin 7 (e.g., the resin reverse surface 72), thereby suppressing discharge between the first die pad 41 and the second die pad 42.

In the electronic device of the present disclosure, the functions of the first electronic component 51 and the second electronic component 52 are not limited to voltage detection. For example, they may also be used for controlling the switching operation of switching elements such as IGBTs or MOSFETs. The electronic device of the present disclosure may be mounted on a wiring board of an inverter device used in an electric vehicle or a hybrid vehicle, for example. In this case, the electronic device of the present disclosure may be used for controlling the switching operation of the switching elements (such as IGBTs or MOSFETs) incorporated in the inverter device. In this case, the second electronic component 52 may be a controller (control element) for a gate driver that drives switching devices such as IGBTs and MOSFETs. The second electronic component 52 includes a circuit for converting control signals inputted from an ECU into PWM control signals, a transmission circuit for transmitting the PWM control signals to the first electronic component 51 (via the third electronic component 53), and a reception circuit for receiving electrical signals from the first electronic component 51 (via the third electronic component 53). The first electronic component 51 may be a gate driver (driving element) for driving the switching elements. The first electronic component 51 includes a reception circuit that receives the PWM control signals from the second electronic component 52 (via the third electronic component 53), a circuit for driving the switching elements in accordance with the PWM control signals; and a transmission circuit for transmitting electrical signals to the second electronic component 52 (via the third electronic component 53), wherein the electrical signals may be output signals from a temperature sensor disposed near a motor of the vehicle.

The electronic device of the present disclosure is not limited to those of the embodiments/variations described above. The configurations of components of the electronic devices of the present disclosure may be varied in many ways. The electronic devices of the present disclosure may include the examples described in the following clauses. Though the same numerical characters used for the components of the above-explained embodiments/variations are used with parentheses in the clauses, this does not mean that the configurations presented in the following clauses are limited to the above-explained embodiments/variations.

Clause 1. An electronic device (A10, A11, A20, A30, A31, A32, A40, A41, A50-A56) comprising: a first electronic component (51); a second electronic component (52); a sealing resin covering the first electronic component (51) and the second electronic component (52); a first lead (11) including a first inner portion (21) covered by the sealing resin and a first outer portion (31) exposed from the sealing resin, the first lead (11) being electrically connected to the first electronic component (51); a second lead (12) including a second inner portion (22) covered by the sealing resin and a second outer portion (32) exposed from the sealing resin, the second lead (12) being electrically connected to the first electronic component (51); a third lead (13) including a third inner portion (23) covered by the sealing resin and a third outer portion (33) exposed from the sealing resin, the third lead (13) being electrically connected to the first electronic component (51); a fourth lead (14) including a fourth inner portion (24) covered by the sealing resin and a fourth outer portion (34) exposed from the sealing resin, the fourth lead (14) being electrically connected to the second electronic component (52); a first die pad (41) supporting the first electronic component (51); and a second die pad (42) supporting the second electronic component (52), wherein the sealing resin includes a plurality of resin side surfaces (73) facing respective orthogonal directions each perpendicular to a thickness direction of the sealing resin (7), the first outer portion (31), the second outer portion (32), and the third outer portion (33) are each exposed from a resin side surface (73) that is different from a resin side surface (73) from which the fourth outer portion (34) is exposed.

Clause 2. The electronic device (A10, A11, A20, A30, A31, A32, A40, A41, A50–A56) according to clause 1, wherein the second inner portion (22) is connected to the first die pad (41).

Clause 3. The electronic device (A10, A11, A20, A30, A31, A32, A50–A56) according to clause 2, wherein the orthogonal directions include a first direction (x), the plurality of resin side surfaces (73) include a first resin side surface (731) and a second resin side surface (732) that face away from each other in the first direction (x), the first outer portion (31), the second outer portion (32) and the third outer portion (33) are exposed from the first resin side surface (731), and the fourth outer portion (34) is exposed from the second resin side surface (732).

Clause 4. The electronic device (A10, A11, A20, A50–A56) according to clause 3, wherein the orthogonal directions include a second direction (y) different from the first direction (x), the first die pad (41) has a first edge (41a) close to the first resin side surface (731) and extending in the second direction (y) as viewed in the thickness direction (z), the second inner portion (22) is connected to an end of the first edge (41a) of the first die pad (41) in the second direction (y).

Clause 5. The electronic device (A10, A11, A50-A56) according to clause 4, wherein the third outer portion (33) is disposed between the first outer portion (31) and the second outer portion (32).

Clause 5-1. The electronic device (A10, A11, A50-A56) according to clause 5, wherein the third outer portion (33) is disposed closer to the second outer portion (32) than to the first outer portion (31) in the second direction (y).

Clause 6. The electronic device (A20) according to clause 4, wherein the second outer portion (32) is disposed between the first outer portion (31) and the third outer portion (33).

Clause 7. The electronic device (A30, A31, A32) according to clause 3, wherein the orthogonal directions include a second direction (y) different from the first direction (x), the first die pad (41) includes a first edge (41a) close to the first resin side surface (731) and extending in the second direction (y) as viewed in the thickness direction (z), the second inner portion (22) is connected to a center of the first edge (41a) of the first die pad (41) in the second direction (y).

Clause 8. The electronic device (A40, A41) according to clause 2, wherein the orthogonal directions include a second direction (y), the plurality of resin side surfaces (73) include a third resin side surface (733) and a fourth resin side surface (734) that face away from each other in the second direction (y), The second outer portion (32) is exposed from at least one of the third resin side surface (733) and the fourth resin side surface (734).

Clause 9. The electronic device (A41) according to clause 8, further comprising a fifth lead (15) including a fifth inner portion (25) covered by the sealing resin (7) and a fifth outer portion (35) exposed from the sealing resin (7), wherein the fifth lead (15) is spaced apart from the first die pad (41).

Clause 10. The electronic device (A41) according to clause 9, further comprising a connecting member (62) having an end connected to the fifth lead (15), wherein the connecting member (62) has another end connected to the first electronic component (51).

Clause 10-1. The electronic device (A41) according to clause 9 or 10, wherein the fifth lead (15) is at a same potential as the second lead (12).

Clause 11. The electronic device (A10, A11, A20, A30, A31, A32, A40, A41, A50–A56) according to any one of clauses 1-10, wherein the fourth inner portion (24) is connected to the second die pad (42).

Clause 11-1. The electronic device (A10, A11, A20, A30, A31, A32, A40, A41, A50–A56) according to any one of clauses 1-11, further comprising a plurality of fourth leads (14) including the above-mentioned fourth lead (14), wherein the plurality of fourth leads include at least one support lead (14A) connected to the second die pad (42) and at least one signal lead (14B) spaced apart from the second die pad (42).

Clause 11-2. The electronic device (A10, A11, A20, A30, A31, A32, A40, A41, A50–A56) according to clause 11-1, wherein a distance between the first outer portion (31) of the first lead (11) and the second outer portion (32) of the second lead (12) is greater than a distance between the fourth outer portions (34) of the plurality of fourth leads (14).

Clause 11-3. The electronic device (A10, A11, A20, A30, A31, A32, A40, A41, A50–A52, A54-A56) according to any one of clauses 1-11, wherein the at least one support lead (14A) is disposed outward of the sealing resin (7) than is the at least one signal lead (14B) along the resin side surface (72) from which the leads (14A, 14B) are exposed.

Clause 12. The electronic device (A32) according to any one of clauses 1-11, further comprising a sixth lead (16) including a sixth outer portion (36) exposed from the sealing resin (7), wherein the sixth outer portion (36) is exposed from a resin side surface (73) of the plurality of resin side surfaces (73) that is different from the resin side surface from which the fourth outer portion (34) is exposed.

Clause 12-1. The electronic device (A10, A20, A31, A40, A41, A50–A53, A55, A56) according to any one of clauses 1-12, wherein the sixth lead (16) is at a potential different from that of the first lead (11), the second lead (12) and the third lead (13).

Clause 13. The electronic device (A10, A20, A31, A40, A41, A50–A53, A55, A56) according to any one of clauses 1-12, further comprising a plurality of second leads (12) including the above-mentioned second lead (12).

Clause 14. The electronic device (A10, A11, A20, A30, A31, A32, A40, A41, A50–A56) according to any one of clauses 1-13, wherein the first electronic component (51) includes a first circuit to be supplied with power via the third lead (13)

Clause 15. The electronic device (A10, A11, A20, A30, A31, A32, A40, A41, A50–A56) according to clause 14, wherein the first electronic component (51) includes a second circuit not to be supplied with the power.

Clause 15-1. The electronic device (A10, A11, A20, A30, A31, A32, A40, A41, A50–A56) according to clause 15, wherein the second circuit is a voltage divider circuit (51A) configured to divide voltage applied between the first lead (11) and the second lead (12).

Clause 15-2. The electronic device (A10, A11, A20, A30, A31, A32, A40, A41, A50–A56) according to clause 15-1, wherein the second circuit generates a voltage signal for detecting a potential difference between the first lead (11) and the second lead (12) by performing dividing of voltage, the voltage signal being outputted to the first circuit.

Clause 16. The electronic device (A10, A11, A20, A30, A31, A32, A40, A41, A50–A56) according to clause 14 or 15, wherein the first circuit is an AD conversion circuit (51B), the second second electronic component (52) includes a DA conversion circuit (52A).

Clause 17. The electronic device (A10, A11, A20, A30, A31, A32, A40, A41, A52–A56) according to any one of clauses 1-16, further comprising a third electronic component (53) configured to relay signals between the first electronic component (51) and the second electronic component (52) in an insulated state.

Clause 18. The electronic device (A10, A11, A20,A30, A31, A32, A40, A41, A52–A56) according to clause 17, wherein the third electronic component (53) issupported on either the first die pad(41) or the second die pad (42).

Clause 18-1. The electronic device (A10, A11, A20, A30, A31, A32, A40, A41, A52–A56) according to clause 17 or 18, wherein the third electronic component (53) is a transformer chip.

### REFERENCE NUMERALS

A10, A11, A20, A30, A31, A32, A40, A41: Electronic device A50 to A56: Electronic device 11: First lead 12: Second lead 13: Third lead 14: Fourth lead 14A: Support lead 14B: Signal lead 15: Fifth Lead 16: Sixth Lead 21: First inner portion 22: Second inner portion 23: Third inner portion 24: Fourth inner portion 25: Fifth inner portion 26: Sixth inner portion 31: First outer portion 311: First mounting portion 312: First root portion 313: First intermediate portion 32: Second outer portion 321: Second mounting portion 322: Second root portion 323: Second intermediate portion 33: Third outer portion 331: Third mounting portion 332: Third root portion 333: Third intermediate portion 34: Fourth outer portion 341: Fourth mounting portion 342: Fourth root portion 343: Fourth intermediate portion 35: Fifth outer portion 351: Fifth mounting portion 352: Fifth root portion 353: Fifth intermediate portion 36: Sixth outer portion 361: Sixth mounting portion 362: Sixth root portion 363: Sixth intermediate portion 41: First die pad 41a to 41d: Edges 42: Second die pad 42a to 42d: Edges 51: First electronic component 51A: Voltage divider circuit 51B: AD conversion circuit 51C: Transmission circuit 511 to 515: Electrode pad 52: Second electronic component 52A: DA conversion circuit 521, 522, 523: Electrode pad 53: Third electronic component 531, 532: Electrode pad 61 to 68: Connecting member 7: Sealing resin 71: Resin obverse surface 72: Resin reverse surface 73: Resin side surface 731: First resin side surface 732: Second resin side surface 733: Third resin side surface 734: Fourth resin side surface R1 to R4: Resistive element

1. An electronic device comprising:
a first electronic component;
a second electronic component;
a sealing resin covering the first electronic component and the second electronic component;
a first lead including a first inner portion covered by the sealing resin and a first outer portion exposed from the sealing resin, the first lead being electrically connected to the first electronic component;
a second lead including a second inner portion covered by the sealing resin and a second outer portion exposed from the sealing resin, the second lead being electrically connected to the first electronic component;
a third lead including a third inner portion covered by the sealing resin and a third outer portion exposed from the sealing resin, the third lead being electrically connected to the first electronic component;
a fourth lead including a fourth inner portion covered by the sealing resin and a fourth outer portion exposed from the sealing resin, the fourth lead being electrically connected to the second electronic component;
a first die pad supporting the first electronic component; and
a second die pad supporting the second electronic component,
wherein the sealing resin includes a plurality of resin side surfaces facing respective orthogonal directions each perpendicular to a thickness direction of the sealing resin,
the first outer portion, the second outer portion, and the third outer portion are each exposed from a resin side surface that is different from a resin side surface from which the fourth outer portion is exposed.

2. The electronic device according to claim 1, wherein the second inner portion is connected to the first die pad.

3. The electronic device according to claim 2, wherein the orthogonal directions include a first direction,
the plurality of resin side surfaces include a first resin side surface and a second resin side surface that face away from each other in the first direction,
the first outer portion, the second outer portion and the third outer portion are exposed from the first resin side surface, and
the fourth outer portion is exposed from the second resin side surface.

4. The electronic device according to claim 3, wherein the orthogonal directions include a second direction different from the first direction,
the first die pad has a first edge close to the first resin side surface and extending in the second direction as viewed in the thickness direction,
the second inner portion is connected to an end of the first edge of the first die pad in the second direction.

5. The electronic device according to claim 4, wherein the third outer portion is disposed between the first outer portion and the second outer portion.

6. The electronic device according to claim 4, wherein the second outer portion is disposed between the first outer portion and the third outer portion.

7. The electronic device according to claim 3, wherein the orthogonal directions include a second direction different from the first direction,
the first die pad includes a first edge close to the first resin side surface and extending in the second direction as viewed in the thickness direction,
the second inner portion is connected to a center of the first edge of the first die pad in the second direction.

8. The electronic device according to claim 2, wherein the orthogonal directions include a second direction,
the plurality of resin side surfaces include a third resin side surface and a fourth resin side surface that face away from each other in the second direction,
the second outer portion is exposed from at least one of the third resin side surface and the fourth resin side surface.

9. The electronic device according to claim 8, further comprising a fifth lead including a fifth inner portion covered by the sealing resin and a fifth outer portion exposed from the sealing resin,
wherein the fifth lead is spaced apart from the first die pad.

10. The electronic device according to claim 9, further comprising a connecting member having an end connected to the fifth lead,
wherein the connecting member has another end connected to the first electronic component.

11. The electronic device according to claim 1, wherein the fourth inner portion is connected to the second die pad.

12. The electronic device according to claim 1, further comprising a sixth lead including a sixth outer portion exposed from the sealing resin,
wherein the sixth outer portion is exposed from a resin side surface of the plurality of resin side surfaces that is different from the resin side surface from which the fourth outer portion is exposed.

13. The electronic device according to claim 1, further comprising a plurality of second leads including the above-mentioned second lead.

14. The electronic device according to claim 1, wherein the first electronic component includes a first circuit to be supplied with power via the third lead.

15. The electronic device according to claim 14, wherein the first electronic component includes a second circuit not to be supplied with the power.

16. The electronic device according to claim 14, wherein the first circuit is an AD conversion circuit,
the second second electronic component includes a DA conversion circuit.

17. The electronic device according to claim 1, further comprising a third electronic component configured to relay signals between the first electronic component and the second electronic component in an insulated state.

18. The electronic device according to claim 17, wherein the third electronic component is supported on either the first die pad or the second die pad.
